(19) United States
(12) Patent Application Publication
(10) Pub. No.: US 2025/0151326 A1
(43) Pub. Date: May 8, 2025

(54) METHOD OF FORMING NANOSTRUCTURE DEVICE BY INTERPOSER LAYER REPLACEMENT AND RELATED STRUCTURES

(71) Applicant: Taiwan Semiconductor Manufacturing Co., Ltd., Hsinchu (TW)

(72) Inventors: Guan-Lin CHEN, Hsinchu (TW); Chih-Hao WANG, Hsinchu (TW); Pei-Yu WANG, Hsinchu (TW); Hsien-Chih HUANG, Hsinchu (TW); Chia-Hao YU, Hsinchu (TW)

(21) Appl. No.: 18/646,578

(22) Filed: Apr. 25, 2024

Related U.S. Application Data
(60) Provisional application No. 63/596,572, filed on Nov. 6, 2023.

(51) Int. Cl. H01L 29/423; H01L 21/8234; H01L 27/088; H01L 29/06; H01L 29/66; H01L 29/775; H01L 29/786

(52) U.S. Cl. CPC H10D 30/6735; H10D 30/014; H10D 30/43; H10D 30/6757; H10D 62/121; H10D 64/017; H10D 64/018; H10D 84/0128; H10D 84/013; H10D 84/038; H10D 84/83

(57) ABSTRACT

A method for forming transistors includes forming a stack of alternating first semiconductor layers and second semiconductor layers on a substrate and forming nanostructure channels and interposers by forming a source/drain opening in a first device region of the substrate. The source/drain opening extending through the first and second semiconductor layers. The method includes, after the forming a source/drain opening, increasing tensile strain of the nanostructure channels, and, after the increasing tensile strain, forming a source/drain in the source/drain opening.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagrammatic cross-sectional side view of a portion of an IC device according to embodiments of the present disclosure.

FIGS. 2A-20 are views of various embodiments of an IC device of at various stages of fabrication according to various aspects of the present disclosure.

FIG. 21 is a flowchart of a method of forming an IC device in accordance with various embodiments.

FIG. 22 is a flowchart of a method of forming an IC device in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms indicative of relative degree, such as “about,” “substantially,” and the like, should be interpreted as one having ordinary skill in the art would in view of current technological norms.

The terms “first,” “second,” “third” and so on may be used herein to describe a sequence of events or sequential order of elements but may be exchanged or varied in some contexts. For example, a second layer may be formed on (e.g., sequentially after) a first layer, but in some contexts the first layer may be referred to as a “second layer,” “third layer,” “fourth layer” or the like, and the second layer may be referred to as a “first layer,” “third layer,” “fourth layer,” or the like.

The term “surrounds” may be used herein to describe a structure that fully or partially encloses another element or structure, for example, in three dimensions. For example, a first structure may “surround” a second structure on four lateral sides (e.g., left, right, front and back) without surrounding the second structure on two vertical sides (e.g., top and bottom). In other example, the first structure may wrap partially around the second structure, for example, by wrapping around three sides (e.g., top, front and back) while leaving other sides (e.g., left, right and bottom) exposed.

Source/drain region(s) may refer to a source or a drain, individually or collectively dependent upon the context.

The present disclosure is generally related to semiconductor devices, and more particularly to field-effect transistors (FETs), such as planar FETs, three-dimensional fin FETs (FinFETs), or nanostructure FETs, such as nanosheet FETs (NSFETs), nanowire FETs (NWFETs), gate-all-around FETs (GAAFETs) and the like.

Tensile strain is beneficial for n-type field-effect transistor (NFET) performance and compressive strain is beneficial for p-type field-effect transistor (PFET) performance. Nanostructures can have tensile strain due to a SiGe interposer, which can improve NFET device performance but may degrade PFET device performance. In NFET devices, Ge % that exceeds 40% may generally not be beneficial due to thickness considerations.

In embodiments of the disclosure, SiGe interposer(s) in NFET device regions can be replaced with substantially pure Ge (e.g., Ge % is substantially 100%) after source/drain etch, which is beneficial to increase tensile strain without degrading thickness. A top nanostructure, which may be a top nanosheet, has less tensile strain than lower nanostructures (e.g., second and third nanosheets) due to the top nanostructure having only single-sided (e.g., bottom) stress while the lower nanostructures have double-sided (e.g., top and bottom) stress. When top SiGe is included, the top nanostructure can also benefit from double-sided stress.

In PFET device regions, the SiGe interposer may be replaced by a dielectric, which changes tensile strain into neutral or compressive strain, which is beneficial to enhance compressive strain after source/drain epitaxy. It should be understood that replacement of the SiGe interposer may be performed in the NFET device regions (e.g., with pure Ge), the PFET device regions (e.g., with dielectric) or both (e.g., pure Ge in NFET device regions and dielectric in PFET device regions).

Nanostructure transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the nanostructure structure.

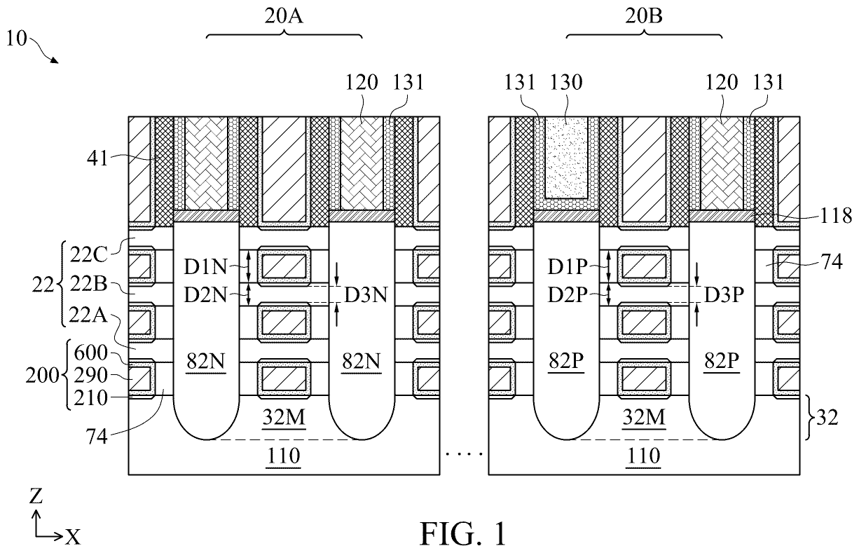

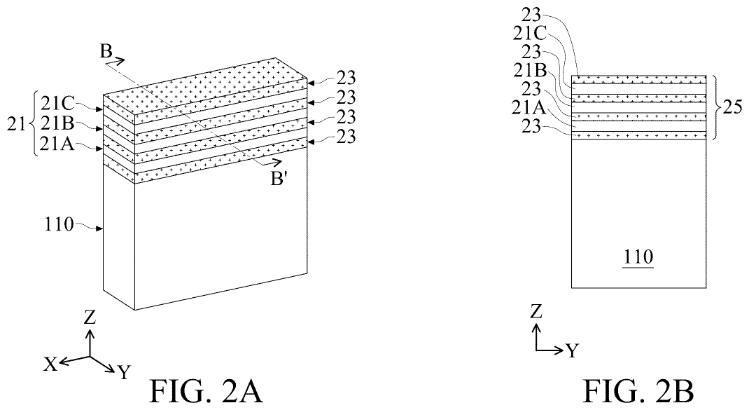

FIG. 1 is a diagrammatic cross-sectional side view of a portion of a nanostructure device 10 in accordance with various embodiments. FIG. 1 illustrates a view in an X-Z plane. The nanostructure device 10 of FIG. 1 is described in detail below to provide context for understanding the technical features and benefits of the various embodiments depicted in FIGS. 2A-20.

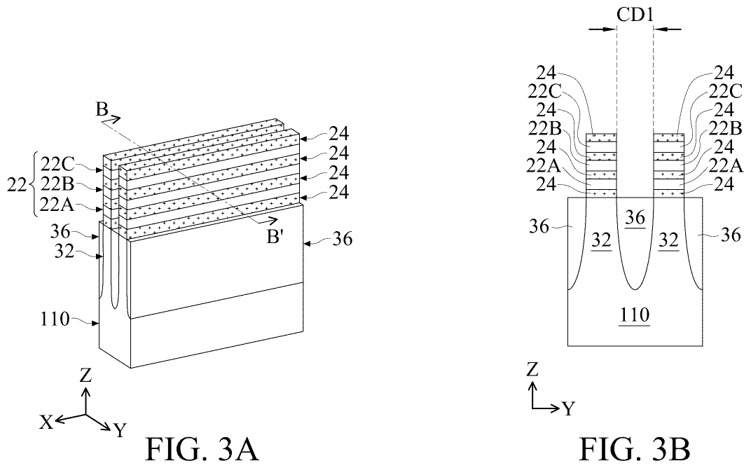

Referring to FIG. 1, nanostructure devices 20A, 20B may be or include one or more N-type FETs (NFETs) or P-type FETs (PFETs). For example, the nanostructure device 20A may be an NFET and the nanostructure device 20B may be a PFET. The nanostructure devices 20A, 20B are formed over and/or in a substrate 110, and generally include gate structures 200 straddling and/or wrapping around semiconductor channels 22A, 22B, 22C, alternately referred to as “nanostructures,” located over semiconductor fins 32 protruding from, and separated by, isolation structures 36 (see FIGS. 3A and 3B). The semiconductor channels 22A, 22B, 22C may be referred to collectively as channels, nanostructures, or nanosheets The gate structure 200 controls electrical current flow through the channels 22.

The nanostructure devices 20A, 20B are shown including three channels 22A, 22B, 22C, which are laterally abutted by source/drain features 82N, 82P, and covered and surrounded by the gate structure 200. Generally, number of the channels 22 is two or more, such as three or four or more. The gate structure 200 controls flow of electrical current through the channels 22A, 22B, 22C to and from the source/drain features 82N, 82P based on voltages applied at the gate structure 200 and at the source/drain features 82N, 82P.

In some embodiments, the fin structure 32 includes silicon. In some embodiments, the nanostructure device 20B includes an NFET, and the source/drain features 82N thereof include silicon phosphorous (SiP), SiAs, SiSb, SiPAs, SiP:As:Sb, combinations thereof, or the like. In some embodiments, the nanostructure device 20A includes a PFET, and the source/drain features 82P thereof include silicon germanium (SiGe), either undoped or doped to form, for example, SiGe:B, SiGe:B:Ga, SiGe:Sn, SiGe:B:Sn, or another appropriate semiconductor material. Generally, the source/drain features 82N, 82P may include any combination of appropriate semiconductor material(s) and appropriate dopant(s). During formation of the source/drain features 82N, 82P, openings may be formed that extend into the fins 32, resulting in mesas 32M that underlie the channels 22 and are between neighboring source/drains 82N and/or 82P.

The channels 22A, 22B, 22C each include a semiconductive material, for example silicon or a silicon compound, such as silicon germanium, or the like. The channels 22A, 22B, 22C are nanostructures (e.g., having sizes that are in a range of a few nanometers) and may also each have an elongated shape and extend in the X-direction. In some embodiments, the channels 22A, 22B, 22C each have a nanowire (NW) shape, a nanosheet (NS) shape, a nanotube (NT) shape, or other suitable nanoscale shape. The cross-sectional profile of the channels 22A, 22B, 22C may be rectangular, round, square, circular, elliptical, hexagonal, or combinations thereof.

In some embodiments, the lengths (e.g., measured in the X-direction) of the channels 22A, 22B, 22C may be different from each other, for example due to tapering during a fin etching process (see FIGS. 3A, 3B). In some embodiments, length of the channel 22C may be less than a length of the channel 22B, which may be less than a length of channel 22A. The channels 22A, 22B, 22C each may not have uniform thickness (e.g., along the X-axis direction), for example due to a channel trimming process used to expand spacing (e.g., measured in the Z-axis direction) between the channels 22A, 22B, 22C to increase gate structure fabrication process window. For example, a middle portion of each of the channels 22A, 22B, 22C may be thinner than the two ends of each of the channels 22A, 22B, 22C. Such shape may be collectively referred to as a “dog-bone” shape. As depicted in FIG. 1, in the nanostructure device 20A, the channel 22B has first thickness D2N at ends thereof and second thickness D3N in a middle portion thereof. Similarly, in the nanostructure device 20B, the channel 22B has first thickness D2P at ends thereof and second thickness D3P in a middle portion thereof.

In some embodiments, the spacing between the channels 22A, 22B, 22C (e.g., between the channel 22B and the channel 22A or the channel 22C) is in a range between about 8 nanometers (nm) and about 12 nm, though ranges exceeding or below the said range may also be beneficial and are contemplated herein. As depicted in FIG. 1, spacing DIN is present between channels 22 (e.g., the channels 22B, 22C) in the nanostructure device 20A, and spacing D1P is present between channels in the nanostructure device 20B. In some embodiments, a thickness (e.g., measured in the Z-direction) of each of the channels 22A, 22B, 22C is in a range between about 5 nm and about 8 nm, though ranges exceeding or below the said range may also be beneficial and are contemplated herein. In some embodiments, a width (e.g., measured in the Y-direction, orthogonal to the X-Z plane) of each of the channels 22A, 22B, 22C is at least about 8 nm, however the width may be less than 8 nm in some embodiments.

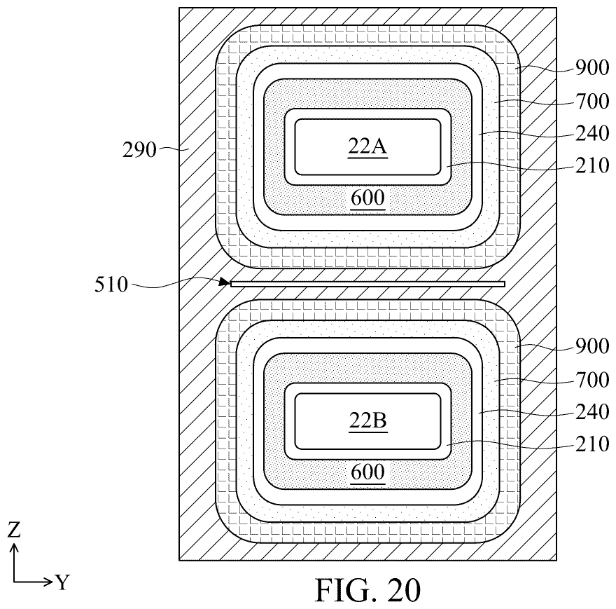

The gate structure 200 is disposed over and between the channels 22A, 22B, 22C, respectively. In some embodiments, the gate structure 200 includes an interfacial layer (IL) 210, one or more gate dielectric layers 600 on the interfacial layer 210 and a metal core layer 290 on the gate dielectric layer 600. Additional layers, such as one or more work function tuning layers 900 (see FIG. 20) may be present on the gate dielectric layer 600 between the gate dielectric layer 600 and the metal core layer 290.

The interfacial layer 210, which may be an oxide of the material of the channels 22A, 22B, 22C, is formed on exposed areas of the channels 22A, 22B, 22C and the top surface of the fin 32 (e.g., the fin mesa 32M). The interfacial layer 210 promotes adhesion of the gate dielectric layers 600 to the channels 22A, 22B, 22C. In some embodiments, the interfacial layer 210 has thickness of about 5 Angstroms (A) to about 50 Angstroms (A). In some embodiments, the interfacial layer 210 has thickness of about 10 A. The interfacial layer 210 having thickness that is too thin may exhibit voids or insufficient adhesion properties. The interfacial layer 210 being too thick consumes gate fill window, which is related to threshold voltage tuning and resistance. In some embodiments, the interfacial layer 210 is doped with a dipole, such as lanthanum, for threshold voltage tuning.

In some embodiments, the gate dielectric layer 600 includes at least one high-k gate dielectric material, which may refer to dielectric materials having a high dielectric constant that is greater than a dielectric constant of silicon oxide (k≈3.9). Example high-k dielectric materials that may be or being included in the gate dielectric layer 600 include HfO₂, HfSiO, HfSiON, HfTaO, HfTiO, HfZrO, ZrO₂, Ta₂O₅, or combinations thereof. In some embodiments, the gate dielectric layer 600 has thickness of about 5 A to about 100 A. The gate dielectric layer 600 may be a single layer or a multilayer.

The gate structure 200 also includes metal core layer 290. The metal core layer 290 may be or include a conductive material such as Co, W, Ru, combinations thereof, or the like. In some embodiments, the metal core layer 290 is or includes a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. Between the channels 22A, 22B, 22C, the metal core layer 290 is circumferentially surrounded (in the cross-sectional view) by the one or more work function metal layers 900, which are then circumferentially surrounded by the gate dielectric layers 600, which are circumferentially surrounded by the interfacial layer 210.

As depicted in FIG. 1, the nanostructure devices 20A, 20B may further include source/drain contacts 120 that are formed over the source/drain features 82N, 82P. The source/drain contacts 120 may include a core layer that is or includes a conductive material such as tungsten, ruthenium, cobalt, copper, titanium, titanium nitride, tantalum, tantalum nitride, iridium, molybdenum, nickel, aluminum, or combinations thereof. The core layer may be surrounded by one or more liner (or, “barrier”) layers, such as SiN or TiN, which help prevent or reduce diffusion of materials from and into the source/drain contacts 120. In some embodiments, height of the source/drain contacts 120 may be in a range of about 1 nm to about 50 nm, though other ranges that, for example, exceed the stated range (e.g., greater than about 50 nm) are also contemplated herein.

Silicide layers 118 may be positioned between the source/drain features 82N, 82P and the source/drain contacts 120, at least to reduce the source/drain contact resistance. In some embodiments, the silicide layer 118 is or includes TiSi, CrSi, TaSi, MoSi, ZrSi, HfSi, ScSi, Ysi, HoSi, TbSl, GdSi, LuSi, DySi, ErSi, YbSi, or the like. In some embodiments, the silicide layer 118 is or includes NiSi, CoSi, MnSi, Wsi, FeSi, RhSi, PdSi, RuSi, PtSi, IrSi, OsSi, or the like. The silicide layer 118 may have thickness in a range of about 1 nm to about 10 nm. Thickness lower than about 1 nm may lead to an insufficient reduction in contact resistance. Thickness above about 10 nm may cause electrical shorting with the nanostructures 22. In some embodiments, the silicide layer 118 is present below, and in contact with, an etch stop layer 131.

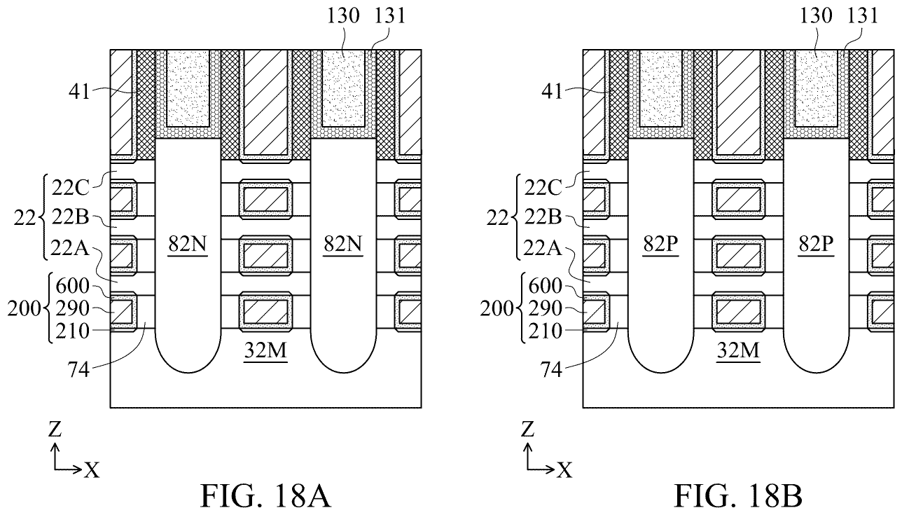

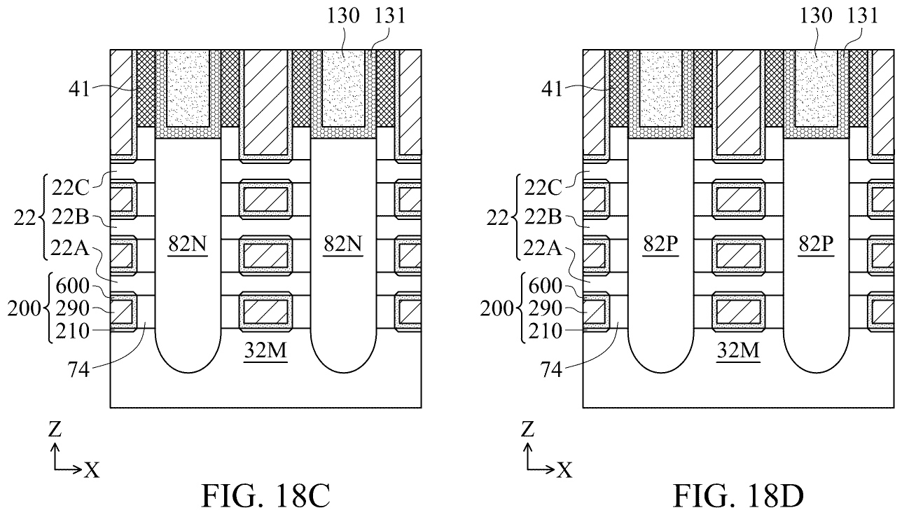

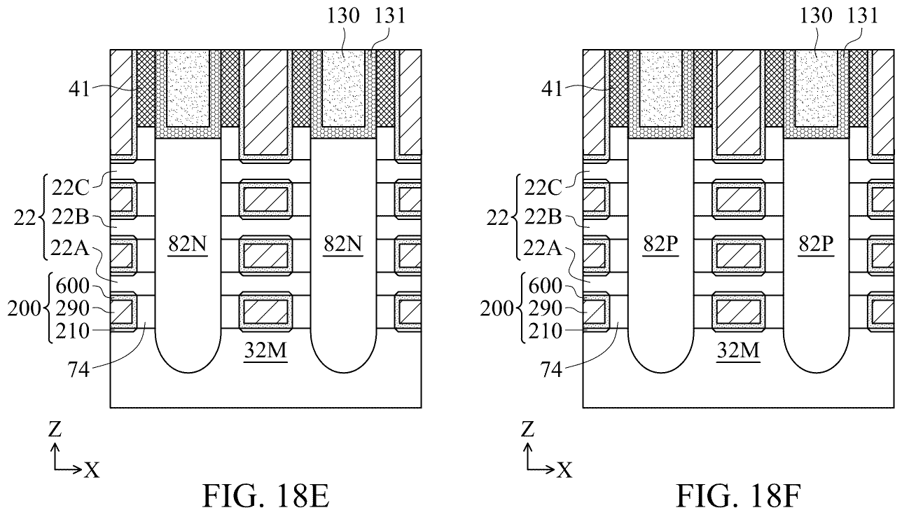

The nanostructure devices 20A, 20B include gate spacers 41 that are disposed on sidewalls of the metal core layer 290, the gate dielectric layer 600 and the IL 210 above the channel 22A, and inner spacers 74 that are disposed on sidewalls of the IL 210 and/or the gate dielectric layer 600 between the channels 22A, 22B, 22C. The inner spacers 74 are disposed between the channels 22A, 22B, 22C. In some embodiments, additional inner spacers 74 may be disposed between the upper surface of the channels 22A and the gate spacers 41, which is depicted at least in FIG. 18F. In the embodiment depicted in FIG. 1, the gate spacers 41 include a single spacer layer. In some embodiments, the gate spacers 41 include a first spacer layer 41A and a second spacer layer 42B on the first spacer layer 41A. The single spacer layer or the first and second spacer layers 41A, 42B of the gate spacers 41 and the inner spacers 74 may each include a dielectric material, for example a low-k material such as SiOCN, SiON, SiN, SiCN, SiOC or the like. In some embodiments, the second spacer layer 42B is not present. One or more of materials of the first spacer layer, the second spacer layer and the inner spacers 74 may be the same as or different from each other. In some embodiments, an upper portion of the second spacer layer (or the gate spacer 41 when the second spacer layer is not present) may be removed partially or fully to decrease aspect ratio of an opening through which the source/drain region 82N, 82P is formed. FIG. 1 depicts an embodiment in which the upper portion of the gate spacer 41 is not thinned. Height of the inner spacers 74 may be the distance DIN, D1P, as depicted in FIG. 1.

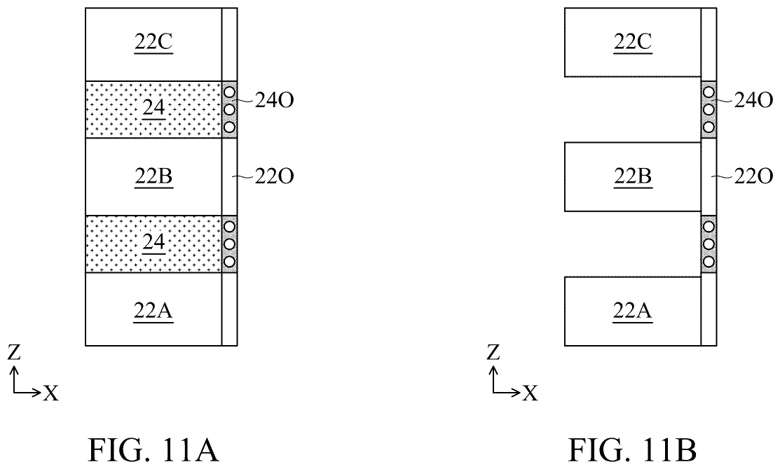

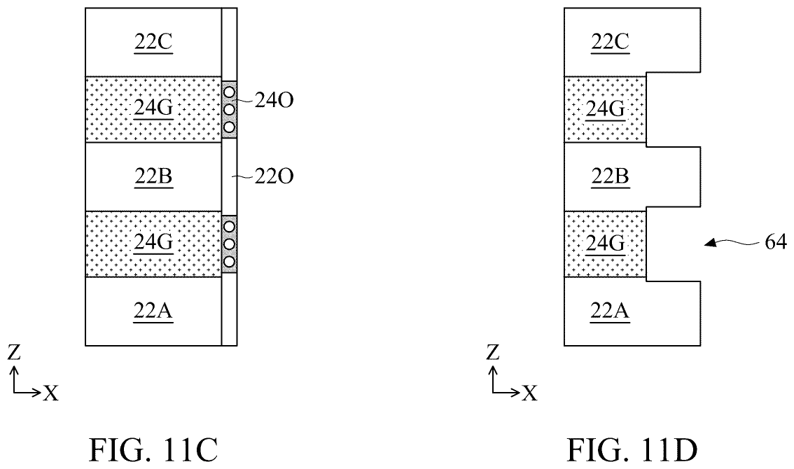

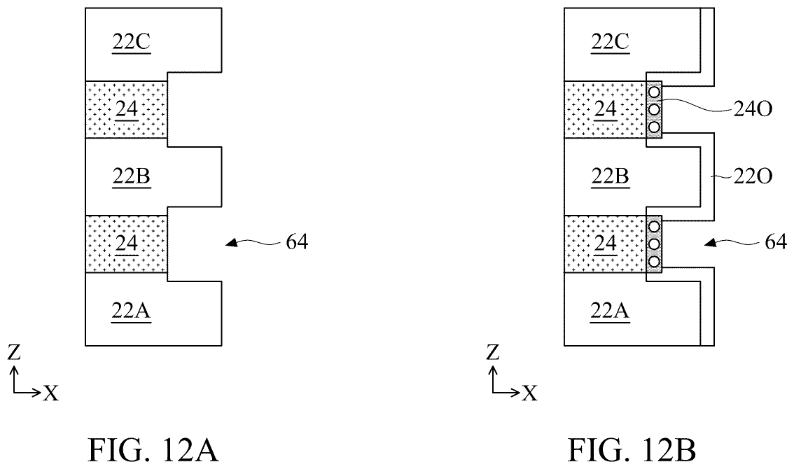

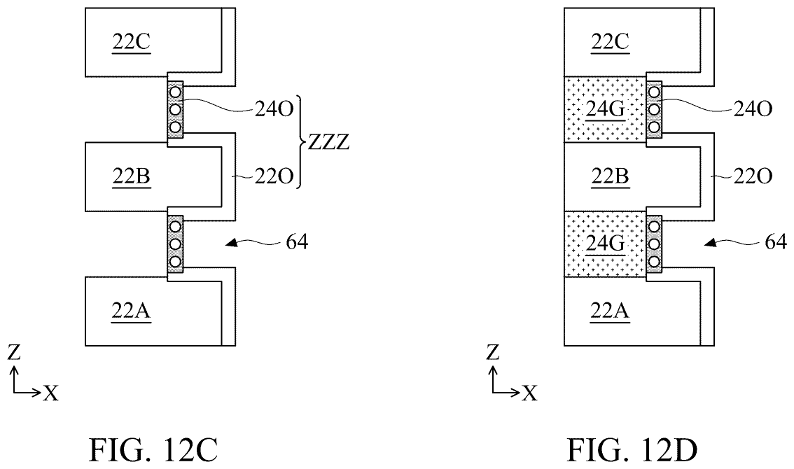

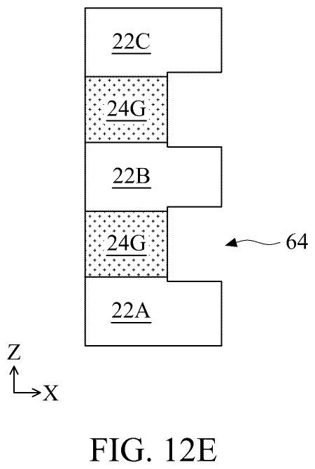

In some embodiments, to improve tensile strain in NFETs (e.g., the nanostructure device 20A), semiconductor layers 24 are replaced by substantially pure germanium layers 24G, which is described at least with reference to FIGS. 11A-12E. The substantially pure Ge layers 24G may have germanium concentration that exceeds about 98%, exceeds about 99%, exceeds about 99.9%, exceeds about 99.99%, or the like. In some embodiments, the layers 24G are high-concentration Ge layers 24G that have Ge concentration that exceeds about 80%, about 85%, about 90%, or the like. In some embodiments, the layers 24G are Ge layers 24G that have Ge concentration that exceeds about 50%, about 60%, about 70%, or the like. In embodiments in which the semiconductor layers 24 associated with NFETs are replaced by substantially pure germanium layers 24G, high-concentration Ge layers 24G or Ge layers 24G as just described, some silicon of the channels 22 of the NFETs is consumed by the replacement process. As such, first and second thicknesses D2N, D3N of the channels 22 in the NFETs (e.g., the nanostructure device 20A) may be smaller than the first and second thicknesses D2P, D3P of the channels 22 in the PFETs (e.g., the nanostructure device 20B), respectively. And, in these embodiments, the thickness DIN of the inner spacers 74 may exceed the thickness D1P of the inner spacers 74 by an amount in a range of about 0.5 nm to about 2 nm. Reference may be made throughout to substantially pure Ge layers 24G, but it should be understood that the description thereof also covers the high-concentration Ge layers 24G and the Ge layers 24G described above.

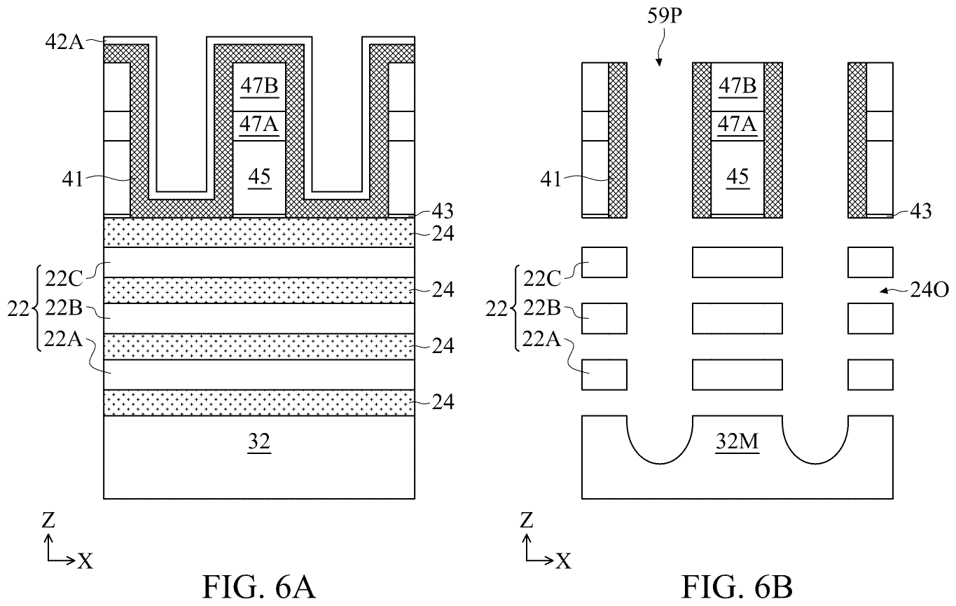

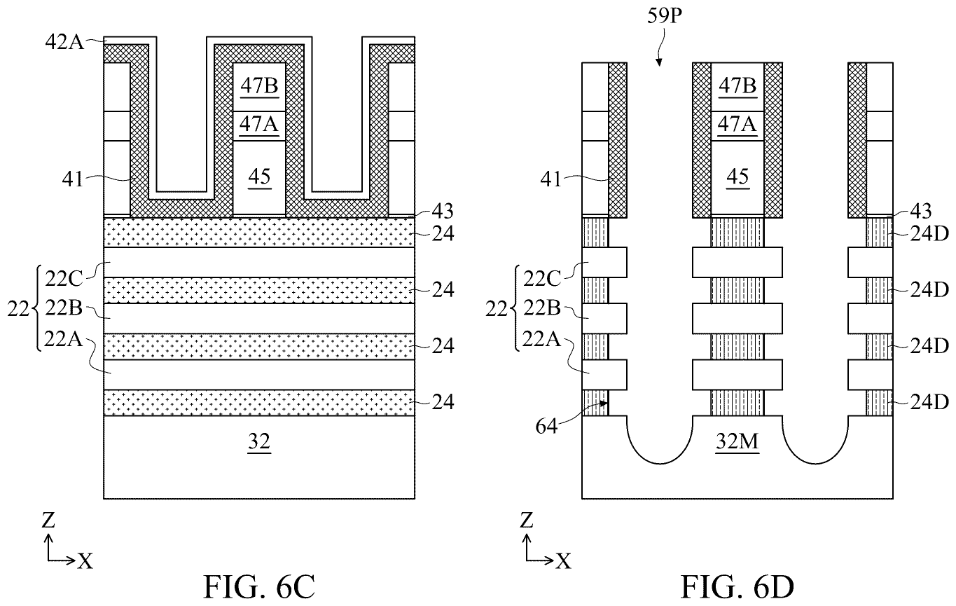

In some embodiments, to improve tensile strain in PFETs (e.g., the nanostructure device 20B), semiconductor layers 24 are replaced by dielectric layers 24D, which is described at least with reference to FIGS. 6A-6D. In embodiments in which the semiconductor layers 24 associated with PFETs are replaced by dielectric layers 24D, some silicon of the channels 22 of the PFETs is consumed by the replacement process. As such, first and second thicknesses D2P, D3P of the channels 22 in the PFETs (e.g., the nanostructure device 20B) may be smaller than the first and second thicknesses D2N, D3N of the channels 22 in the NFETs (e.g., the nanostructure device 20A), respectively. And, in these embodiments, the thickness D1P of the inner spacers 74 may exceed the thickness DIN of the inner spacers 74 by an amount in a range of about 0.5 nm to about 2 nm.

In some embodiments, a first replacement process is performed to replace the semiconductor layers 24 with the substantially pure Ge layers 24G in the NFETs (e.g., the nanostructure device 20A) and a second replacement process is performed to replace the semiconductor layers 24 with the dielectric layers 24D in the PFETs (e.g., the nanostructure device 20B). In some embodiments, the first and second replacement processes consume substantially the same amount of silicon of the channels 22 in the NFETs and the PFETs, such that the first thicknesses D2N, D2P are substantially equal to each other, the second thicknesses D3N, D3P are substantially equal to each other and the thicknesses DIN, D1P are substantially equal to each other. In some embodiments, the amounts of silicon consumed by the first and second replacement processes are different from each other, such that the thicknesses DIN, D2N, D3N are different than (e.g., exceed or are smaller than) the corresponding thicknesses D1P, D2P, D3P.

In embodiments in which the semiconductor layers 24 are replaced with the substantially pure Ge layers 24G in the NFETs, nanostructure lattice constant of the channels 22 of the NFETs (e.g., the nanostructure device 20A) exceeds mesa lattice constant of the fin mesa 32M by an amount in a range of about 0.5% to about 4%. In such embodiments, the nanostructure lattice constant of the channels 22 of the NFETs (e.g., the nanostructure device 20A) exceeds the nanostructure lattice constant of the channels 22 of the PFETs (e.g., the nanostructure device 20B) by an amount in a range of about 0.5% to about 4%. In embodiments in which no inner spacer 74 is present on the upper surface of the uppermost channel 22C, lattice constant of the channel 22C may be smaller than lattice constant of the channels 22B, 22A by an amount in a range of about 0.1% to about 2%. The channels 22B, 22A may have increased strain compared to the channel 22C due to having the substantially pure Ge layers or interposers 24G on top and bottom sides thereof compared to the channel 22C having the interposer 24G only on the bottom side thereof. In some embodiments, an inner spacer 74 is present on the upper surface of the uppermost channel 22C. In such embodiments, the strain and/or lattice constant of the channel 22C and the strain and/or lattice constant of the channels 22B, 22A may be substantially equal to each other.

In embodiments in which the semiconductor layers 24 are replaced with dielectric layers or interposers 24D, the lattice constant of channels 22 of the PFETs may be smaller than that of the fin mesa 32M thereunder by an amount in a range of about 0.5% to about 2% due to compressive strain. The compressive strain may result from the dielectric interposers 24D, high Ge concentration in SiGe (e.g., about 40% to about 80% Ge concentration) in the p-type source/drains 82P, or both.

The nanostructure devices 20A, 20B may further include an interlayer dielectric (ILD) 130. In FIG. 1, the ILD 130 is only depicted in the nanostructure device 20B, but it should be understood that the nanostructure device 20A and/or the nanostructure device 20B may include the ILD 130. The ILD 130 provides electrical isolation between the various components of the nanostructure devices 20A, 20B discussed above, for example between neighboring pairs of the source/drain contacts 120. An etch stop layer 131 may be formed prior to forming the ILD 130 and may be positioned laterally between the ILD 130 and gate spacers 41 and vertically between the ILD 130 and the source/drain features 82N, 82P. In some embodiments, the etch stop layer 131 is or includes SiN, SiCN, SiC, SiOC, SiOCN, HfO2, ZrO2, ZrAlOx, HfAlOx, HfSiOx, Al2O3, or other suitable material. In some embodiments, thickness of the etch stop layer is in a range of about 1 nm to about 5 nm. In some embodiments, where the ILD 130 is not present (e.g., is removed completely prior to formation of the source/drain contacts 120), the etch stop layer 131 may be in contact with the source/drain contact 120. The etch stop layer 131 may be trimmed, for example, in the X-axis direction prior to formation of the source/drain contact 120 to improve fill quality of the source/drain contact 120.

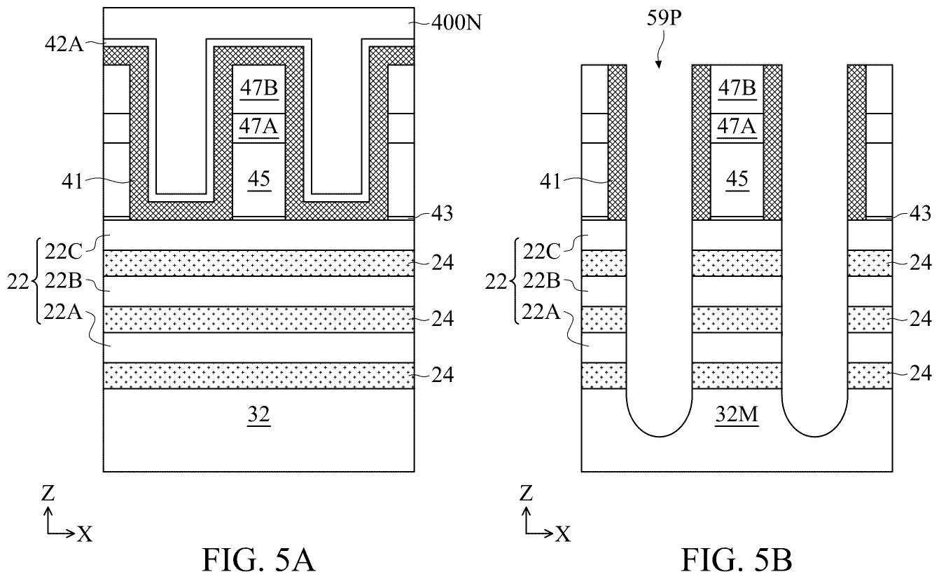

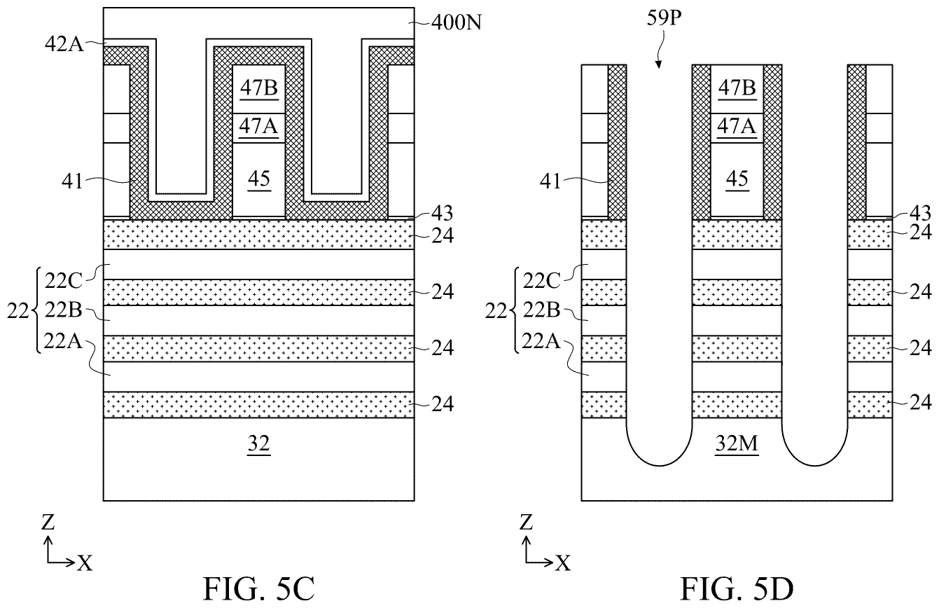

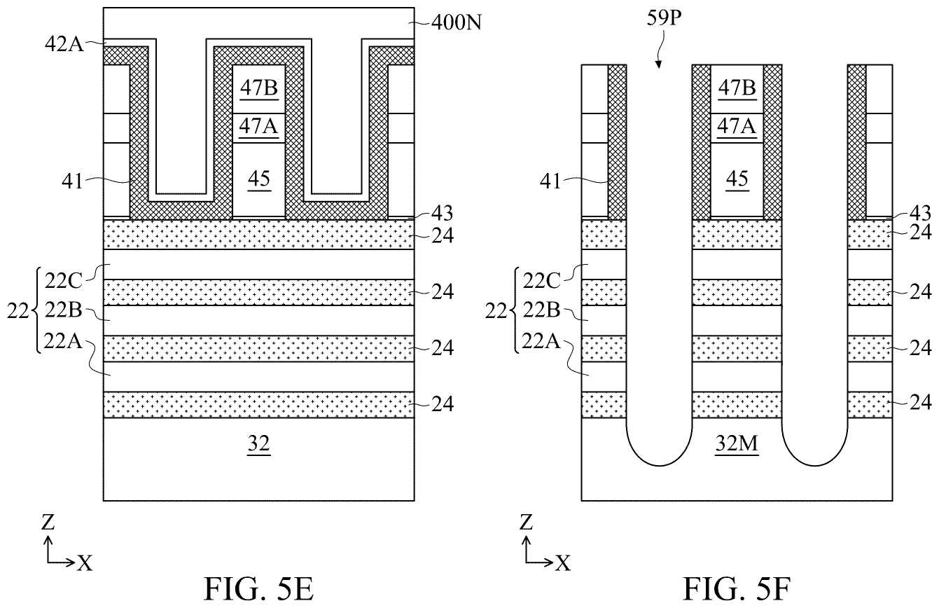

FIGS. 2A through 20 are views of intermediate stages in the manufacturing of FETs, such as nanostructure FETs, in accordance with some embodiments. FIGS. 2A-4C, 5C-5F, 6A-6D, 7C-7F, 8C-8F, 9C-9F, 10C-10F, 13C-13F, 14C-14F, 15C-15F, 16C-16F, 17C-17F, 18C-18F, illustrate some embodiments in which the top layer of the fins is a semiconductor nanostructure 24. Whereas FIGS. 5A, 5B, 7A, 7B, 8A, 8B, 9A, 9B, 10A, 10B, 13A, 13B, 14A, 14B, 15A, 15B, 16A, 16B, 17A, 17B, 18A and 18B illustrate some embodiments in which the top layer of the fins is a channel 22C. FIGS. 5A, 5B, 7A, 7B, 8A, 8B, 9A, 9B, 10A, 10B, 13A, 13B, 14A, 14B, 15A, 15B, 16A, 16B, 17A, 17B, 18A and 18B are views of forming NFETs and PFETs in which the semiconductor layers 24 in the NFETs are replaced with substantially pure Ge layers 24G and no inner spacer 74 is present on an upper surface of the uppermost channels 22C. FIGS. 5C, 5D, 7C, 7D, 8C, 8D, 9C, 9D, 10C, 10D, 13C, 13D, 14C, 14D, 15C, 15D, 16C, 16D, 17C, 17D, 18C and 18D are views of forming NFETs and PFETs in which the semiconductor layers 24 in the NFETs are replaced with substantially pure Ge layers 24G and inner spacers 74 are present on the upper surface of the uppermost channels 22C. FIGS. 5E, 5F, 7E, 7F, 8E, 8F, 9E, 9F, 10E, 10F, 13E, 13F, 14E, 14F, 15E, 15F, 16E, 16F, 17E, 17F, 18E and 18F are views of forming NFETs and PFETs in which the semiconductor layers 24 in the NFETs are replaced with substantially pure Ge layers 24G, the semiconductor layers 24 in the PFETs are replaced with dielectric layers 24D and inner spacers 74 are present on the upper surface of the uppermost channels 22C. Process operations that are similar across all three process flows just described may be described only once with reference to a single embodiment such as, for example, the embodiment depicted in FIGS. 5A and 5B. Differences in other embodiments, such as depicted in FIGS. 5C and 5D and FIGS. 5E and 5F, may be described without repeating description provided for FIGS. 5A and 5B, and so on throughout the description. It should be noted that the embodiments described in FIGS. 2A-20 may be combined to form additional embodiments and that some acts may be omitted in some embodiments to form additional embodiments. For example, in some embodiments, replacement of the semiconductor layers 24 with the dielectric layers 24D may be performed while replacement with the substantially pure Ge layers 24G is omitted. In another example, in the embodiments described with reference to FIGS. 5E, 5F, 7E, 7F, 8E, 8F, 9E, 9F, 10E, 10F, 13E, 13F, 14E, 14F, 15E, 15F, 16E, 16F, 17E, 17F, 18E and 18F, the top inner spacers 74 on the upper surface of the channels 22C may be omitted. Namely, the feature of replacing with the dielectric layers 24D described with reference to FIGS. 5E, 5F, 7E, 7F, 8E, 8F, 9E, 9F, 10E, 10F, 13E, 13F, 14E, 14F, 15E, 15F, 16E, 16F, 17E, 17F, 18E and 18F maybe combined with the feature of forming single-sided strain on the channels 22C described with reference to FIGS. 5A, 5B, 7A, 7B, 8A, 8B, 9A, 9B, 10A, 10B, 13A, 13B, 14A, 14B, 15A, 15B, 16A, 16B, 17A, 17B, 18A and 18B.

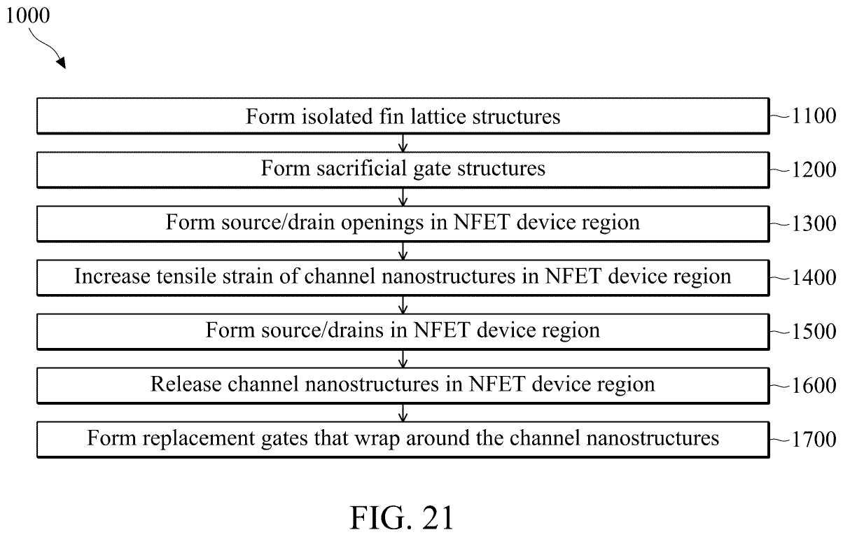

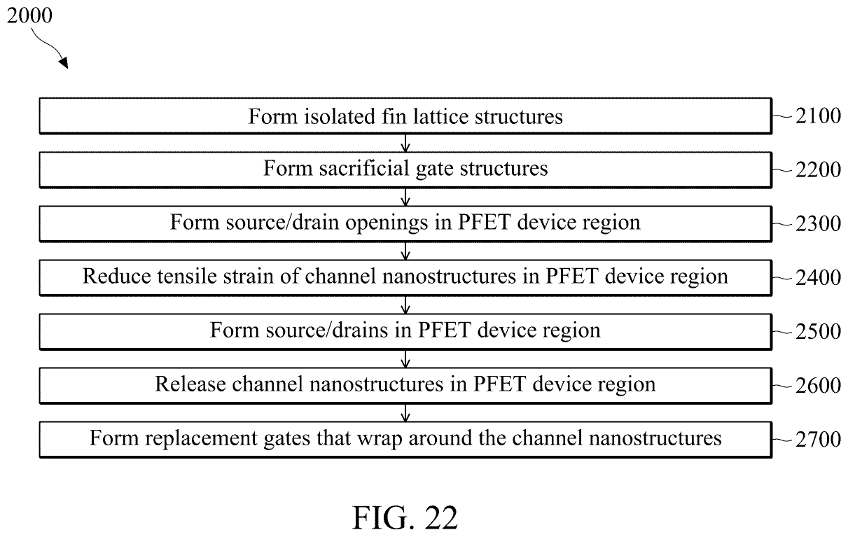

FIGS. 21 and 22 depict flowcharts of methods 1000, 2000 for forming an IC device or a portion thereof from a workpiece, according to one or more aspects of the present disclosure. Methods 1000, 2000 are merely examples and not intended to limit the present disclosure to what is explicitly illustrated in methods 1000, 2000. Additional acts can be provided before, during and after the methods 1000, 2000 and some acts described can be replaced, eliminated, or moved around for additional embodiments of the method. Not all acts are described herein in detail for reasons of simplicity. Methods 1000, 2000 are described below in conjunction with fragmentary perspective and/or cross-sectional views of a workpiece, shown in FIGS. 2A-20, at different stages of fabrication according to embodiments of methods 1000, 2000. For avoidance of doubt, throughout the figures, the X direction is perpendicular to the Y direction and the Z direction is perpendicular to both the X direction and the Y direction. It is noted that, because the workpiece may be fabricated into a semiconductor device, the workpiece may be referred to as the semiconductor device as the context requires.

In FIG. 2A and FIG. 2B, a substrate 110 is provided. The substrate 110 may be a semiconductor substrate, such as a bulk semiconductor, or the like, which may be doped (e.g., with a p-type or an n-type dopant) or undoped. The semiconductor material of the substrate 110 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as single-layer, multi-layered, or gradient substrates may be used.

Further in FIG. 2A and FIG. 2B, a multi-layer stack 25 or “lattice” is formed over the substrate 110 of alternating layers of first semiconductor layers 21A, 21B, 21C (collectively referred to as first semiconductor layers 21) and second semiconductor layers 23. In some embodiments, the first semiconductor layers 21 may be formed of a first semiconductor material suitable for n-type nano-FETs, such as silicon, silicon carbide, or the like, and the second semiconductor layers 23 may be formed of a second semiconductor material suitable for p-type nano-FETs, such as silicon germanium or the like. Each of the layers 21, 23 of the multi-layer stack 25 may be epitaxially grown using a process such as chemical vapor deposition (CVD), atomic layer deposition (ALD), vapor phase epitaxy (VPE), molecular beam epitaxy (MBE), or the like. In some embodiments, germanium concentration of the second semiconductor layers 23 is less than about 40%, which is beneficial when forming the lattice 25 and provides some tensile strain to channels 22 that are formed from the first semiconductor layers 21. To increase the tensile strain, the second semiconductor layers 23 may be replaced in a later operation with germanium layers 24G having germanium concentration that exceeds 40%, such as 50%, 60%, 70%, 80%, 90%, 95%, 98%, 99%, 99.9%, 99.99% or the like. In some embodiments, the germanium layers 24G are pure germanium layers 24G having germanium concentration that is 100% or substantially 100%. Throughout the description, germanium concentration may refer to atomic percent of germanium in the germanium layer 24G. Germanium concentration may refer to weight percent, mole fraction or another suitable measure. When the germanium layers 24G are silicon germanium layers having increased germanium concentration, a molar ratio of germanium to silicon may be used instead of absolute concentration. For example, a high-concentration germanium layer 24G in accordance with various embodiments may have a molar ratio of germanium to silicon that is in a range of about 50:50 to about 99:1.

Three layers of the first semiconductor layers 21 and four layers of the second semiconductor layers 23 are illustrated in FIGS. 2A and 2B. In some embodiments, the multi-layer stack 25 may include fewer or additional pairs of the first semiconductor layers 21 and the second semiconductor layers 23. Although the multi-layer stack 25 is illustrated as including a second semiconductor layer 23 as the bottommost layer, in some embodiments, the bottommost layer of the multi-layer stack 25 may be a first semiconductor layer 21. In some embodiments, the topmost layer of the multi-layer stack 25 is a first semiconductor layer 21 instead of the second semiconductor layer 23 depicted in FIGS. 2A and 2B. For example, the topmost second semiconductor layer 23 depicted in FIGS. 2A and 2B may be omitted.

Due to high etch selectivity between the first semiconductor materials and the second semiconductor materials, the second semiconductor layers 23 of the second semiconductor material may be removed without significantly removing the first semiconductor layers 21 of the first semiconductor material, thereby allowing the first semiconductor layers 21 to be patterned to form channel regions of nano-FETs. In some embodiments, the first semiconductor layers 21 are removed and the second semiconductor layers 23 are patterned to form channel regions. The high etch selectivity allows the first semiconductor layers 21 of the first semiconductor material to be removed without significantly removing the second semiconductor layers 23 of the second semiconductor material, thereby allowing the second semiconductor layers 23 to be patterned to form channel regions of nano-FETs.

In FIG. 3A and FIG. 3B, fins 32 are formed in the substrate 110 and nanostructures 22, 24 are formed in the multi-layer stack 25 corresponding to act 1100 of FIGS. 21, 22. In some embodiments, the nanostructures 22, 24 and the fins 32 may be formed by etching trenches in the multi-layer stack 25 and the substrate 110. The etching may be any acceptable etch process, such as a reactive ion etch (RIE), neutral beam etch (NBE), the like, or a combination thereof. The etching may be anisotropic. First nanostructures 22A, 22B, 22C (also referred to as “channels 22” below) are formed from the first semiconductor layers 21, and second nanostructures 24 are formed from the second semiconductor layers 23. Distance CD1 between adjacent fins 32 and nanostructures 22, 24 may be from about 18 nm to about 100 nm, though narrower distances that are less than about 18 nm are also contemplated herein. A portion of the device 10 is illustrated in FIGS. 3A and 3B including two fins 32 for simplicity of illustration. The processes 1000, 2000 illustrated in FIGS. 21, 22 may be extended to any number of fins, and are not limited to the two fins 32 shown in FIGS. 3A-20.

The fins 32 and the nanostructures 22, 24 may be patterned by any suitable method. For example, one or more photolithography processes, including double-patterning or multi-patterning processes, may be used to form the fins 32 and the nanostructures 22, 24. Generally, double-patterning or multi-patterning processes combine photolithography and self-aligned processes, allowing for pitches smaller than what is otherwise obtainable using a single, direct photolithography process. As an example of one multi-patterning process, a sacrificial layer may be formed over a substrate and patterned using a photolithography process. Spacers are formed alongside the patterned sacrificial layer using a self-aligned process. The sacrificial layer is then removed, and the remaining spacers may then be used to pattern the fins 32.

FIGS. 3A and 3B illustrate the fins 32 having tapered sidewalls, such that a width of each of the fins 32 and/or the nanostructures 22, 24 continuously increases in a direction towards the substrate 110. In such embodiments, each of the nanostructures 22, 24 may have a different width and be trapezoidal in shape. In other embodiments, the sidewalls are substantially vertical (non-tapered), such that width of the fins 32 and the nanostructures 22, 24 is substantially similar, and each of the nanostructures 22, 24 is rectangular in shape.

In FIGS. 3A and 3B, isolation regions, features or structures 36, which may be shallow trench isolation (STI) regions, features or structures, are formed adjacent the fins 32. The isolation regions 36 may be formed by depositing an insulation material over the substrate 110, the fins 32, and nanostructures 22, 24, and between adjacent fins 32 and nanostructures 22, 24. The insulation material may be an oxide, such as silicon oxide, a nitride, the like, or a combination thereof, and may be formed by high-density plasma CVD (HDP-CVD), flowable CVD (FCVD), the like, or a combination thereof. In some embodiments, a liner (not separately illustrated) may first be formed along surfaces of the substrate 110, the fins 32, and the nanostructures 22, 24. Thereafter, a core material, such as those discussed above may be formed over the liner.

The insulation material undergoes a removal process, such as a chemical mechanical polish (CMP), an etch-back process, combinations thereof, or the like, to remove excess insulation material over the nanostructures 22, 24. Top surfaces of the nanostructures 22, 24 may be exposed and level with the insulation material after the removal process is complete.

The insulation material is then recessed to form the isolation regions 36. After recessing, the nanostructures 22, 24 and upper portions of the fins 32 may protrude from between neighboring isolation regions 36. The isolation regions 36 may have top surfaces that are flat as illustrated, convex, concave, or a combination thereof. In some embodiments, the isolation regions 36 are recessed by an acceptable etching process, such as an oxide removal using, for example, dilute hydrofluoric acid (dHF), which is selective to the insulation material and leaves the fins 32 and the nanostructures 22, 24 substantially unaltered.

FIGS. 2A through 3B illustrate one embodiment (e.g., etch last) of forming the fins 32 and the nanostructures 22, 24. In some embodiments, the fins 32 and/or the nanostructures 22, 24 are epitaxially grown in trenches in a dielectric layer (e.g., etch first). The epitaxial structures may comprise the alternating semiconductor materials discussed above, such as the first semiconductor materials and the second semiconductor materials.

In FIG. 3A and FIG. 3B, appropriate wells (not separately illustrated) may be formed in the fins 32, the nanostructures 22, 24, and/or the isolation regions 36. Using masks, an n-type impurity implant may be performed in p-type regions of the substrate 110, and a p-type impurity implant may be performed in n-type regions of the substrate 110. Example n-type impurities may include phosphorus, arsenic, antimony, or the like. Example p-type impurities may include boron, boron fluoride, indium, or the like. An anneal may be performed after the implants to repair implant damage and to activate the p-type and/or n-type impurities. In some embodiments, in situ doping during epitaxial growth of the fins 32 and the nanostructures 22, 24 may obviate separate implantations, although in situ and implantation doping may be used together.

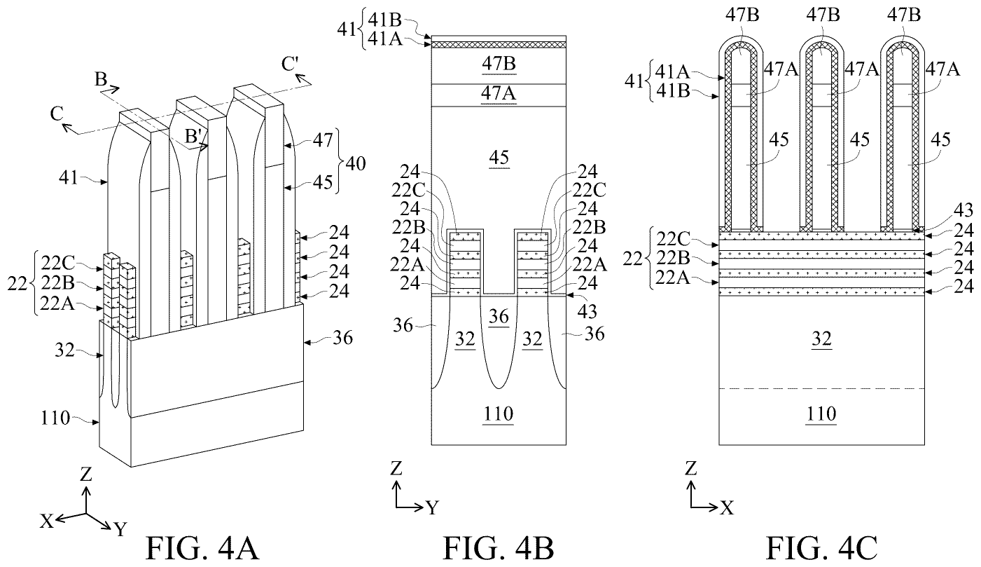

In FIGS. 4A-4C, dummy or sacrificial gate structures 40 are formed over the fins 32 and/or the nanostructures 22, 24, corresponding to act 1200 of FIGS. 21, 22. A dummy or sacrificial gate layer 45 is formed over the fins 32 and/or the nanostructures 22, 24. The dummy gate layer 45 may be or include materials that have a high etching selectivity relative to the isolation regions 36. The dummy gate layer 45 may be a conductive, semiconductive or non-conductive material and may be or include amorphous silicon, polycrystalline-silicond (polysilicon), poly-crystalline silicon-germanium (poly-SiGe), metallic nitrides, metallic silicides, metallic oxides, and metals. The dummy gate layer 45 may be deposited by physical vapor deposition (PVD), CVD, sputter deposition, or other techniques for depositing the selected material.

A mask layer 47 is formed over the dummy gate layer 45, and may include, for example, silicon nitride, silicon oxynitride, or the like. In some embodiments, the mask layer 47 includes a first mask layer 47A in contact with the dummy gate layer 45, and a second mask layer 47B overlying and in contact with the first mask layer 47A. The first mask layer 47A may be or include the same or different material as that of the second mask layer 47B.

In some embodiments, a gate dielectric layer 43 is formed before the dummy gate layer 45 between the dummy gate layer 45 and the fins 32 and/or the nanostructures 22, 24.

A spacer layer 41 is formed over sidewalls of the mask layer 47 and the dummy gate layer 45. The spacer layer 41 is or includes an insulating material, such as SiOCN, SiOC, SiCN or the like (or any of the materials described with reference to FIG. 1) and may have a single-layer structure or a multi-layer structure including a plurality of dielectric layers, in accordance with some embodiments. The spacer layer 41 may be formed by depositing a spacer material layer (not shown) over the mask layer 47 and the dummy gate layer 45. Portions of the spacer material layer between dummy gate structures 40 are removed using an anisotropic etching process, in accordance with some embodiments. In some embodiments, as shown in detail in FIGS. 4B, 4C, the spacer layer 41 includes a first spacer layer 41A in contact with the nanostructure 22C or the topmost second semiconductor layer 24, the gate dielectric layer 43, the dummy gate layer 45 and the first and second mask layers 47A, 47B. A second spacer layer 42B of the spacer layer 41 may be in contact with the first spacer layer 41A. The first spacer layer 41A may be or include the same or different material as that of the second spacer layer 42B.

As described previously, FIGS. 5A, 5B, 7A, 7B, 8A, 8B, 9A, 9B, 10A, 10B, 13A, 13B, 14A, 14B, 15A, 15B, 16A, 16B, 17A, 17B, 18A and 18B are views of forming NFETs and PFETs in which the semiconductor layers 24 in the NFETs are replaced with substantially pure Ge layers 24G and no inner spacer 74 is present on an upper surface of the uppermost channels 22C. FIGS. 5C, 5D, 7C, 7D, 8C, 8D, 9C, 9D, 10C, 10D, 13C, 13D, 14C, 14D, 15C, 15D, 16C, 16D, 17C, 17D, 18C and 18D are views of forming NFETs and PFETs in which the semiconductor layers 24 in the NFETs are replaced with substantially pure Ge layers 24G and inner spacers 74 are present on the upper surface of the uppermost channels 22C. FIGS. 5E, 5F, 7E, 7F, 8E, 8F, 9E, 9F, 10E, 10F, 13E, 13F, 14E, 14F, 15E, 15F, 16E, 16F, 17E, 17F, 18E and 18F are views of forming NFETs and PFETs in which the semiconductor layers 24 in the NFETs are replaced with substantially pure Ge layers 24G, the semiconductor layers 24 in the PFETs are replaced with dielectric layers 24D and inner spacers 74 are present on the upper surface of the uppermost channels 22C.

FIGS. 5A, 5C, 5E, 7A, 7C, 7E, 8A, 8C, 8E, 9A, 9C, 9E, 10A, 10C, 10E, 11A, 11C, 11E, 12A, 12C, 12E, 13A, 13C, 13E, 14A, 14C, 14E, 15A, 15C, 15E, 16A, 16C, 16E, 17A, 17C, 17E, 18A, 18C, 18E, 19A, 19C and 19E depict processing associated with devices in NFET regions. FIGS. 5B, 5D, 5F, 7B, 7D, 7F, 8B, 8D, 8F, 9B, 9D, 9F, 10B, 10D, 10F, 11B, 11D, 11F, 12B, 12D, 12F, 13B, 13D, 13F, 14B, 14D, 14F, 15B, 15D, 15F, 16B, 16D, 16F, 17B, 17D, 17F, 18B, 18D, 18F, 19B, 19D and 19F depict processing associated with devices in PFET regions.

Description will generally be given with reference to FIGS. 5A, 5B, 7A, 7B, 8A, 8B, 9A, 9B, 10A, 10B, 13A, 13B, 14A, 14B, 15A, 15B, 16A, 16B, 17A, 17B, 18A and 18B without repeating description for other corresponding figures.

In FIGS. 5A-5F, first source/drain openings 59P are formed in the PFET region by performing an etching process to etch the portions of protruding fins 32 and/or nanostructures 22, 24 that are not covered by dummy gate structures 40 and mask layer 400N, corresponding to act 2300 of FIG. 22. The first source/drain openings 59P extend through the stacks of nanostructures 22, 24. The mask layer 400N covers and protects semiconductor device features in the NFET region(s) during formation of the first source/drain openings 59P in the PFET region(s). Prior to forming the first source/drain openings 59P, a first sacrificial spacer layer 42A may be formed on the spacer layer 41. The first sacrificial spacer layer 42A may be or include one or more dielectric materials, such as SiO, SiC, SiN, SiCN, SION, SiOCN or the like. The first sacrificial spacer layer 42A protects underlying layers in the NFET device region(s) from damage in subsequent operations.

The recessing that forms the first source/drain openings 59P may be anisotropic, such that the portions of fins 32 directly underlying dummy gate structures 40 and the spacer layer 41 are protected and are not substantially etched. The top surfaces of the recessed fins 32 may be substantially coplanar with the top surfaces of the isolation regions 36, in accordance with some embodiments. The top surfaces of the recessed fins 32 may be lower than the top surfaces of the isolation regions 36, in accordance with some other embodiments, as depicted in FIG. 5B. In such embodiments, a plurality of fin mesas 32M may be formed in the fin 32. FIG. 5B depicts three vertical stacks of nanostructures 22, 24 following the etching process for simplicity. In general, the etching process may be used to form fewer or additional vertical stacks of nanostructures 22, 24 over the fins 32 than those depicted. In some embodiments, the second mask layer 47B is exposed following the etching process, for example, due to removal of upper portions of the spacer layer 41 during the etching process. In some embodiments, the first sacrificial spacer layer 42A is removed entirely in the PFET device region(s), as depicted in FIGS. 5B, 5D, 5F. Removal of the first sacrificial spacer layer 42A is beneficial for increasing opening size for forming a second sacrificial spacer layer 42B in a later operation.

In FIGS. 5C-5F, the optional top second semiconductor layer 24 is included between the sacrificial gate structures 40 and the uppermost channel 22C. The first source/drain openings 59P extend through the top second semiconductor layer 24 and the stacks of nanostructures 22, 24 and may extend into the fin 32, as described with reference to FIGS. 5A and 5B.

FIGS. 6A-6D are diagrammatic cross-sectional views illustrating a process for forming dielectric layers 24D or “dielectric interposer layers 24D” that replace the nanostructures 24 between channels 22 and reduce tensile strain of the channels 22, corresponding to act 2400 of FIG. 22. Compressive strain is beneficial for PFET performance. Source/drain epitaxy can form compressive strain in the channels 22 in the PFET device region. Prior to source/drain epitaxy, the channels 22 can have tensile strain due to the SiGe interposers (e.g., the nanostructures 24) in contact therewith, which can degrade PFET performance. To reduce tensile strain in the PFET device region(s) prior to source/drain epitaxy, the SiGe interposers 24 may be replaced with the dielectric interposer layers 24D, which reduces tensile strain to neutral or compressive strain. Then, following source/drain epitaxy, compressive strain can be increased relative to embodiments in which the SiGe interposers 24 are not replaced.

In FIG. 6A, prior to forming the first source/drain openings 59P, the spacer layer 41 and the first sacrificial spacer layer 42A are present on the sacrificial gate structures 40 and the upper surface of the topmost nanostructure 24 or the topmost channel 22C when the topmost nanostructure 24 is omitted. Formation of the sacrificial gate structures 40 and the spacer layer 41 is described with reference to FIGS. 4A-4C.

In FIGS. 6A and 6B, following formation of the sacrificial gate structures 40 and the spacer layer 41, the first source/drain openings 59P are formed in the PFET region(s) while the NFET region(s) is protected by the spacer layer 41. One or more etch operations may be performed that break through the spacer layer 41, which may expose the stack of nanostructures 22, 24 and may also expose the second mask layer 47B, as depicted in FIG. 6B. This is described with reference to FIGS. 4A-4C.

Following breaking through the spacer layer 41, which exposes the upper surface of the topmost nanostructure 24 or the topmost channel 22C when the topmost nanostructure 24 is omitted, the first source/drain openings 59P are formed in the PFET region(s) as described with reference to FIGS. 5A-5F.

Following formation of the first source/drain openings 59P, the nanostructures 24 are removed by a suitable etching operation, forming openings 240 between the channels 22. For example, the etching operation may be or include one or more isotropic etching operations, such as a wet etch, that removes the nanostructures 24 at a faster rate than the channels 22. In some embodiments, the channels 22 are thinned slightly by the etching operation that removes the nanostructures 24. In some embodiments, the nanostructures 24 are removed entirely by the etching operation. In some embodiments, the nanostructures 24 are partially (e.g., mostly removed) by the etching operation, such that some material (e.g., low-concentration SiGe) of the nanostructures 24 remains on upper or lower surfaces of one or more of the channels 22.

In FIGS. 6C and 6D, the NFET region(s) remains protected while dielectric interposer layers 24D are formed in the openings 240 that are adjacent to (e.g., above and/or below) the channels 22 where the nanostructures 24 were previously disposed. The dielectric interposer layers 24D may be formed by a suitable deposition operation, such as a PVD, CVD, ALD or the like. In some embodiments, the dielectric interposer layers 24D are or include a dielectric material, such as SiO, SiOC, SiC, SiN, SiON, SiOCN, combinations thereof (e.g., multilayers thereof) or the like. Other dielectric materials, such as HfO, Al₂O₃ or the like may be included in the dielectric interposer layers 24D. Initially, one or more dielectric material layers including one or more of the dielectric materials just mentioned may be formed between and optionally outside the openings 240. In some embodiments, the dielectric material layer(s) may partially or completely fill the first source/drain openings 59P. Namely, the dielectric material layer(s) may be present on side surfaces of the spacer layer 41 and upper surfaces of the fin 32 exposed by the first source/drain openings 59P.

Following deposition of the dielectric material layer(s), one or more etching operations may be performed that recess the dielectric material layer(s) to form the dielectric interposer layers 24D. In some embodiments, the dielectric interposer layer(s) 24D have width after recessing that is less than that of the channels 22 (e.g., in the X-axis direction depicted in FIG. 6D). Inner spacer recesses 64 in which inner spacers will be formed may be present at ends of the dielectric interposer layer(s) 24D. In some embodiments, width of the inner spacer recesses 64 is in a range of about 0.5 nm to about 3 nm.

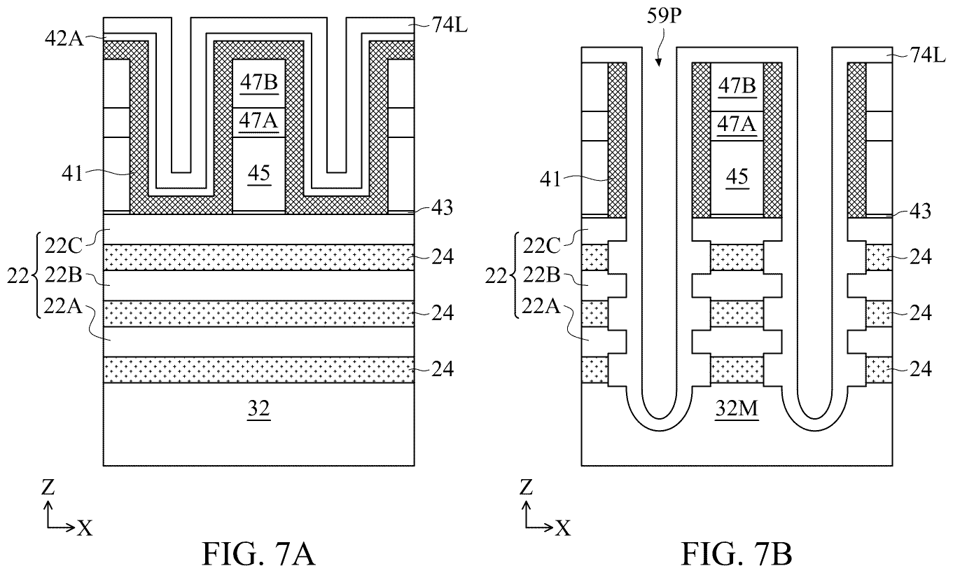

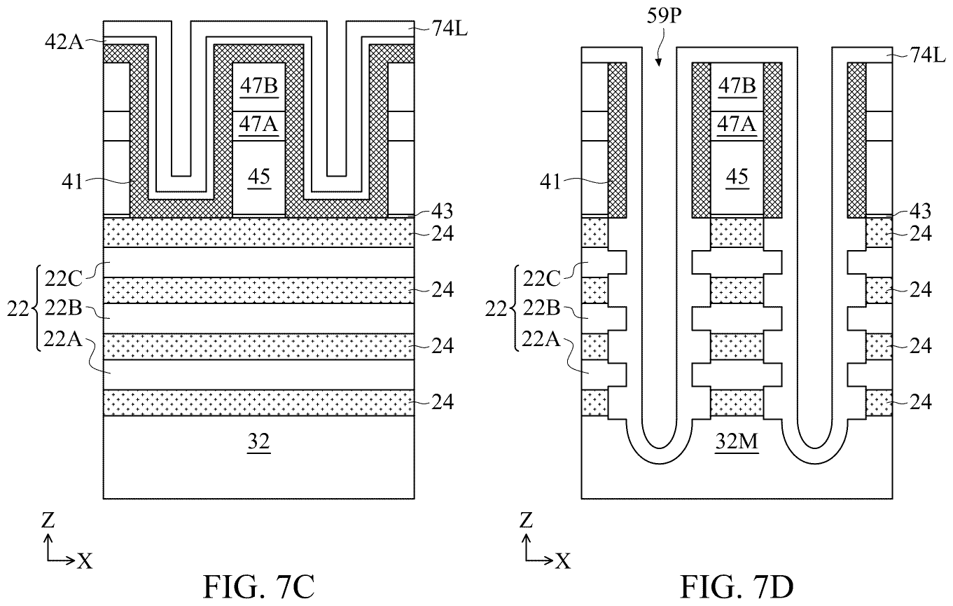

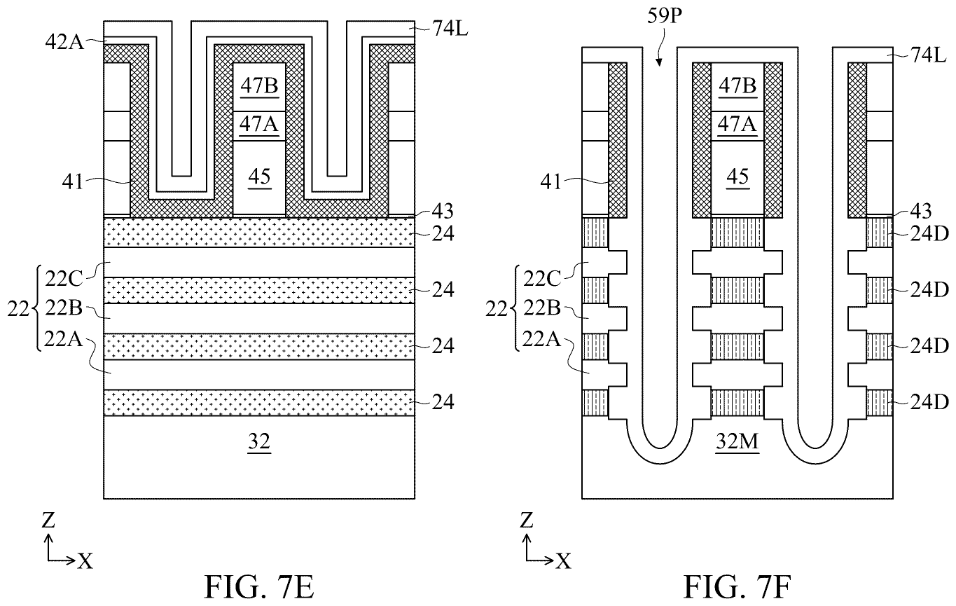

In FIGS. 7A-7F, an inner spacer layer 74L is formed. FIGS. 7E and 7F continue after the forming dielectric layers 24D described with reference to FIGS. 6A-6D, in which recesses 64 are formed (see FIG. 6D). In FIGS. 7A-7D, a selective etching process is performed to recess end portions of the nanostructures 24 exposed by openings in the spacer layer 41 without substantially attacking the nanostructures 22. After the selective etching process in FIGS. 7A-7D, recesses similar to the recesses 64 depicted in FIG. 6D are formed in the nanostructures 24 at locations where the removed end portions used to be. Then, following formation of the recesses in FIGS. 7A-7D or the recesses 64 in FIG. 6D, an inner spacer layer 74L is formed to fill (partially or entirely) the recesses in the nanostructures 24 formed by the previous selective etching process, as depicted in FIGS. 7A-7F. The inner spacer layer 74L may be a suitable dielectric material, such as SiN, SiCN, SiOCN, SiOC or the like, formed by a suitable deposition method such as PVD, CVD, ALD, or the like. In the NFET device region(s) depicted in FIGS. 7A, 7C, 7E, the first source/drain openings 59 are not present, such that the inner spacer layer 74L is deposited on the spacer layer 41 and/or the first sacrificial spacer layer 42A.

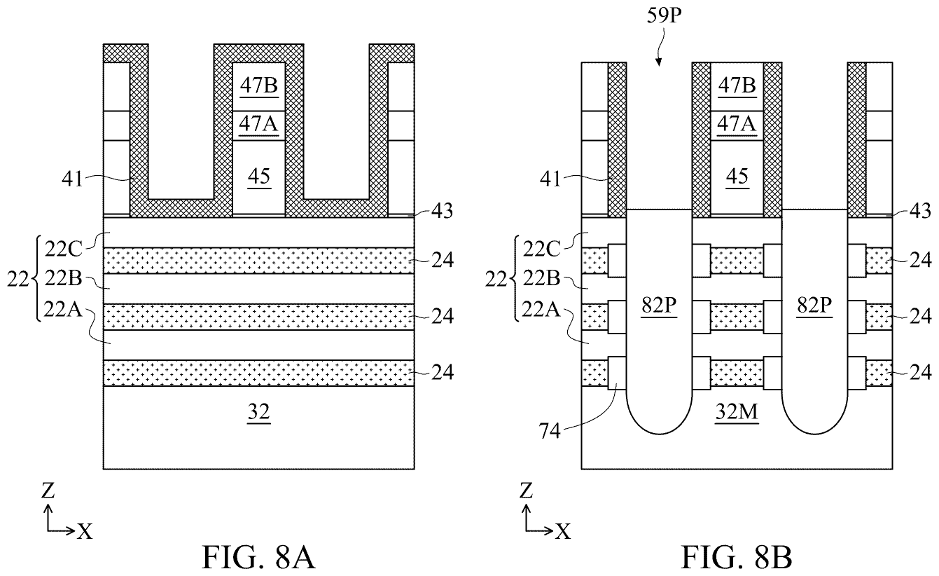

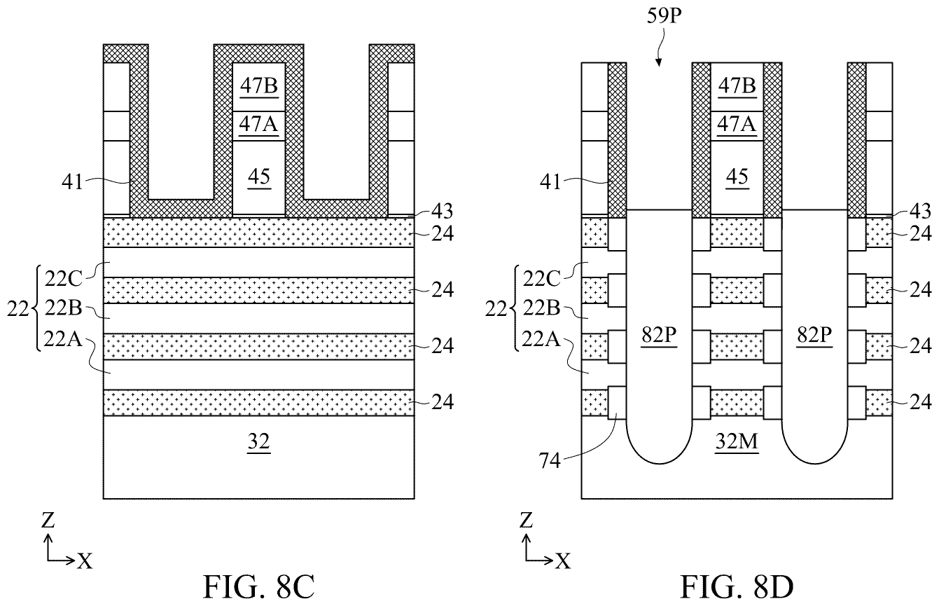

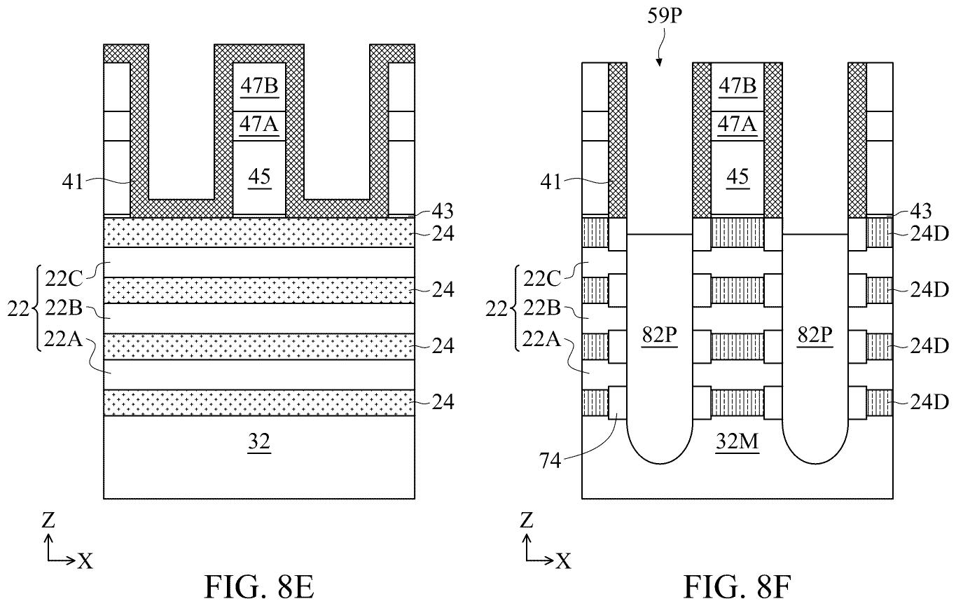

In FIGS. 8A-8F, following formation of the inner spacer layer 74L, an etching process, such as an anisotropic etching process, is performed to remove portions of the inner spacer layer 74L disposed outside the recesses, for example, on side surfaces of the nanostructures 22 and upper surfaces of the fins 32. The remaining portions of the inner spacer layer 74L (e.g., portions disposed inside the recesses in the nanostructures 24) form the inner spacers 74. The etching process that forms the inner spacers 74 may remove the inner spacer layer 74L in the NFET device region(s), as depicted in FIGS. 8A, 8C, 8E.

Then, in FIGS. 8A-8F, first source/drain regions 82P or “first source/drains 82P” are formed in accordance with various embodiments, corresponding to act 2500 of FIG. 22. FIG. 8B depicts formation of p-type source/drains 82P. The first source/drain regions 82P may be epitaxially grown from epitaxial material(s). In some embodiments, the first source/drain regions 82P exert stress in the respective channels 22A, 22B, 22C, thereby improving performance. The first source/drain regions 82P are formed such that each dummy gate structure 40 is disposed between respective neighboring pairs of the first source/drain regions 82P. In some embodiments, the spacer layer 41 separates the first source/drain regions 82P from the sacrificial gate layer 45 by an appropriate lateral distance to prevent electrical bridging to subsequently formed gates of the resulting device. The first source/drain regions 82P may be or include Si:B, Si:Ga, SiGe:B, SiGe:B:Ga, SiGe:Sn, SiGe:B:Sn or the like. The first source/drain regions 82P may exert a compressive strain in the channel regions. Following formation of the first source/drain regions 82P, the first sacrificial spacer layer 42A may be removed in the NFET device region(s), as depicted in FIGS. 8A, 8C, 8E.

As depicted in FIG. 8F, in some embodiments, the first source/drains 82P have upper surfaces that are between upper surfaces of the uppermost channels 22C and upper surfaces of the uppermost inner spacers 74. Namely, the first source/drains 82P may extend upward to a level that is lower than a bottom surface of the sacrificial gate layer 45.

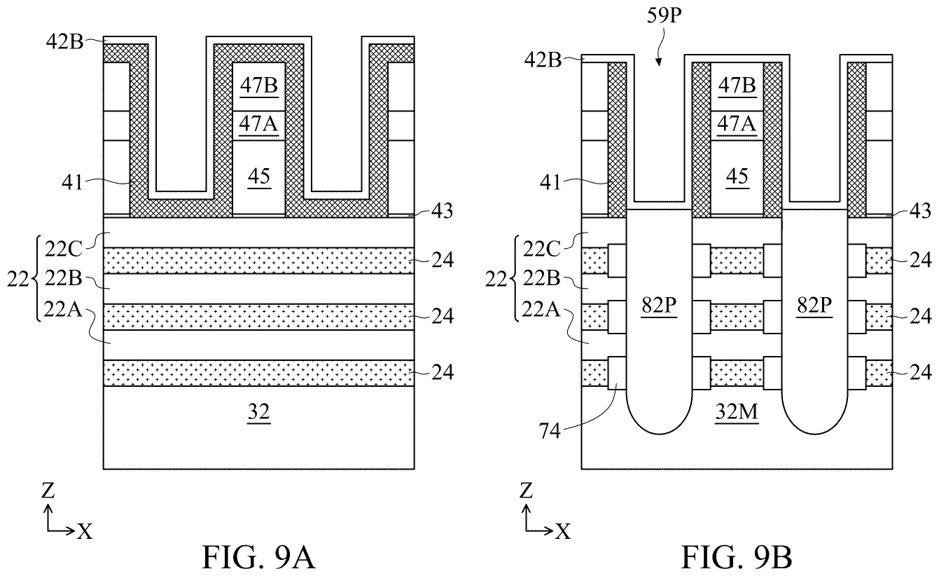

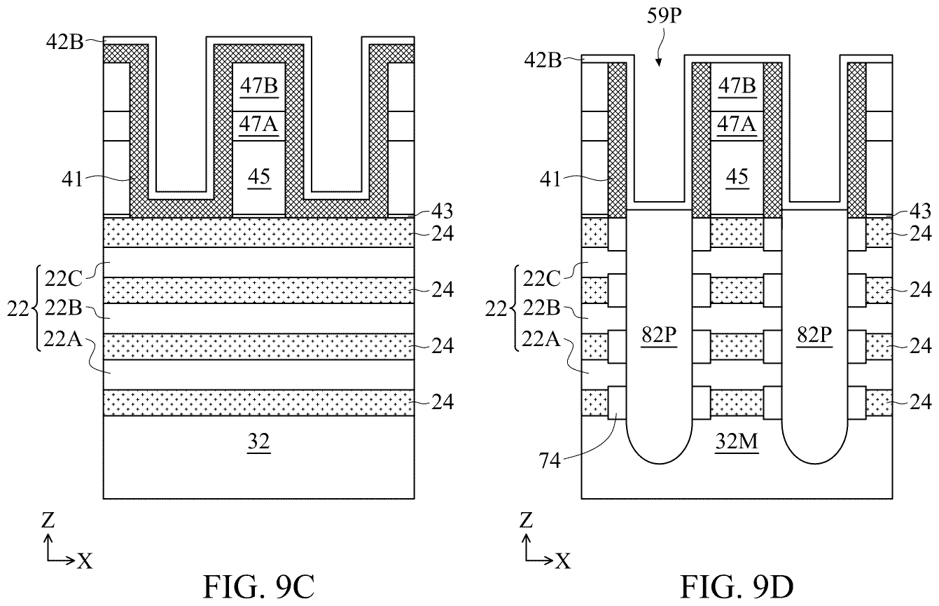

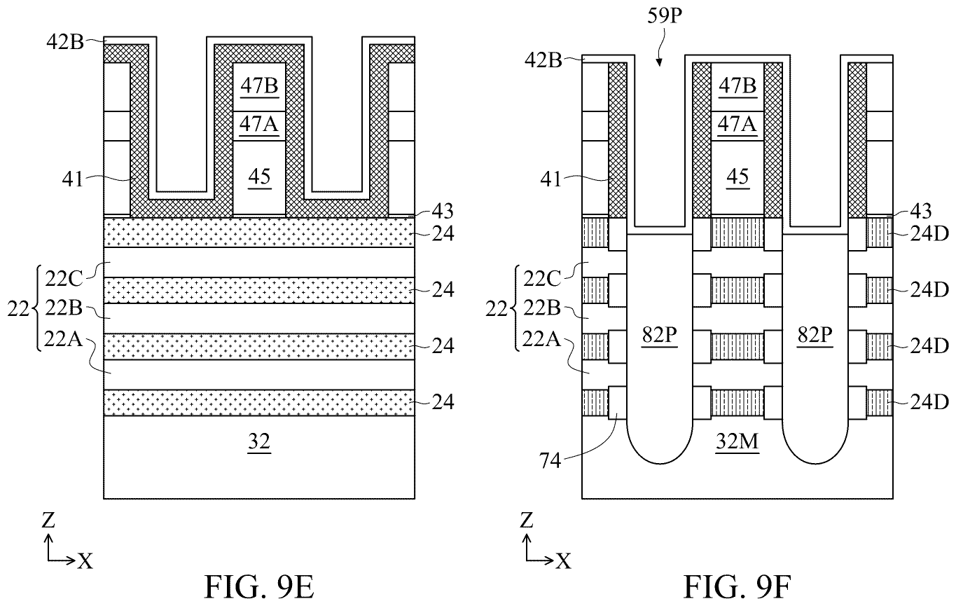

In FIGS. 9A-9F, following formation of the first source/drains 82P, a second spacer layer 42B is formed on exposed surfaces in the NFET and PFET device regions. The second sacrificial spacer layer 42B may be or include one or more dielectric materials, such as SiN, SiCN, SiON, SiOCN, SiC, SiO, combinations thereof or the like and may be deposited by a suitable deposition process, such as a PVD, CVD, ALD or the like. In some embodiments, the second sacrificial spacer layer 42B is or includes a same material as or different material than the first sacrificial spacer layer 42A. The second sacrificial spacer layer 42B is beneficial to protect the PFET device region(s) in subsequent operations.

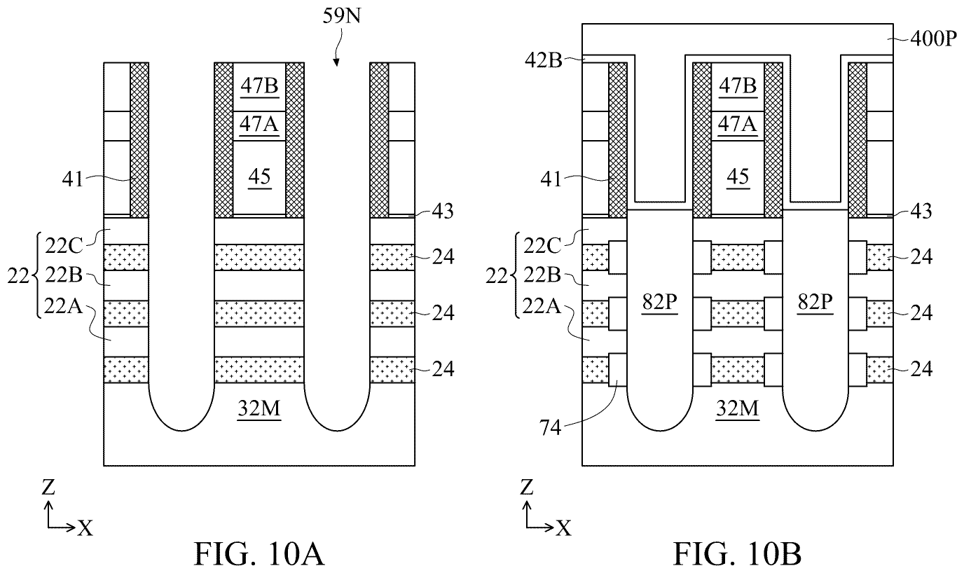

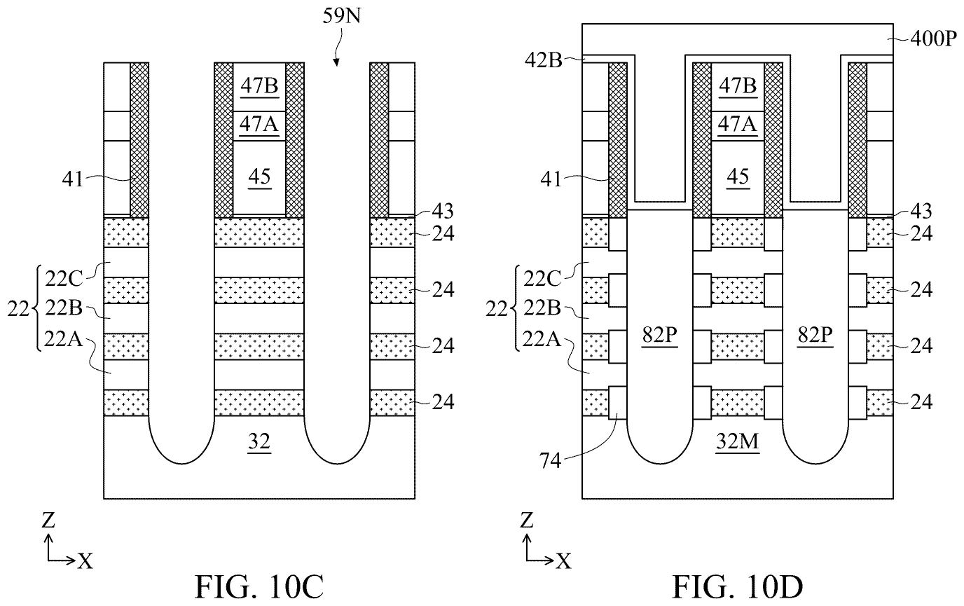

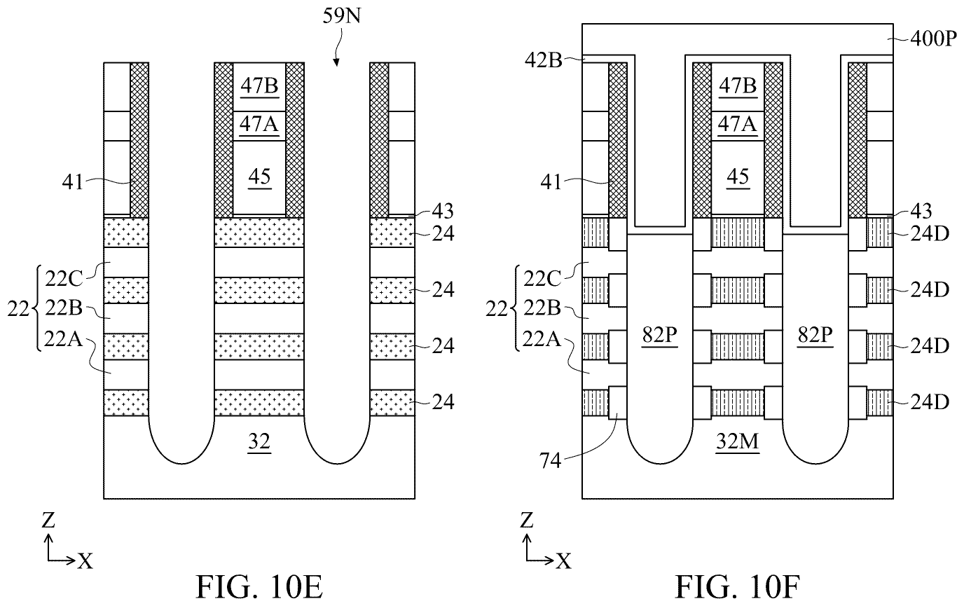

In FIGS. 10A-10F, following formation of the second sacrificial spacer layer 42B, a second mask layer 400P that protects the PFET device region(s) while exposing the NFET device region(s) is formed. Then, second source/drain openings 59N are formed in the NFET device region(s), as depicted in FIGS. 10A, 10C, 10E, corresponding to act 1300 of FIG. 21. Formation of the second source/drain openings 59N is similar in most respects to that of forming the first source/drain openings 59P described with reference to FIGS. 5A-6D and may include one or more anisotropic etch operations that remove material of the second sacrificial spacer layer 42B, the spacer layer 41, the channels 22, the nanostructures 24 and the fins 32. Fin mesas 32M may be formed laterally between the second source/drain openings 59N, as depicted.

FIGS. 11A-12E are diagrammatic cross-sectional views of processes for replacing the nanostructures 24 in the NFET device region(s) with Ge layers 24G in accordance with various embodiments. The Ge layers 24G have ends that are set back from outer side surfaces of the channels 22 to form recesses 64 in which inner spacers 74 are formed. In FIGS. 11A-11D, the Ge layers 24G are formed followed by formation of the recesses 64. In FIGS. 12A-12E, the recesses 64 are formed followed by formation of the Ge layers 24G. It should be understood that the embodiments described with reference to FIGS. 11A-11D and FIGS. 12A-12E may be combined with any of the embodiments described with reference to FIGS. 2A-10F and 13A-20.

In FIGS. 11A-12E, the SiGe nanostructures 24 are replaced with interposers 24G that are beneficial for increasing tensile strain of the channels 22 in the NFET device region(s), corresponding to act 1400 of FIG. 21. In the description with reference to FIGS. 11A-12E, the replacement interposers 24G are described as pure or substantially pure germanium interposers, high germanium concentration interposers or germanium-based semiconductor or “germanium-alloy” interposers that have germanium concentration exceeding about 50%. The replacement interposers 24G have the function of increasing tensile strain in the channels 22. Increasing the tensile strain may include via lattice mismatch and/or thermal expansion mismatch. In some embodiments, the replacement interposers 24G include a material that can increase tensile strain of the silicon channels 22 but is different from the pure or substantially pure germanium, high germanium concentration semiconductor or germanium-based semiconductor having germanium concentration exceeding about 50%.

In FIG. 11A, one or more operations may be performed that form oxide layers 220, 240 on outer side surfaces of the channels 22 and the nanostructures 24, respectively. The oxide layers 220, 240 may be formed by one or more chemical oxide formation processes, such as exposure to oxygen gas and/or a cleaning process. The oxide layer 220 is a SiO layer that protects the channels 22 during growth of germanium layers 24G in subsequent operations, such that the germanium layers 24G are grown selectively on exposed upper and/or lower surfaces of the channels 22 without being substantially grown on the outer side surfaces of the channels 22. The oxide layer 240 is a porous layer of SiGeO following the chemical oxide formation process. The porosity of the oxide layer 240 allows for selective removal of the nanostructures 24 and selective growth of the germanium layers 24G. Thickness of the oxide layers 220, 240 may be the same as each other, substantially the same as each other or different from each other. For example, thickness of SiGeO of the oxide layer 240 may increase faster than, slower than or at the same rate as thickness of the SiO of the oxide layer 220 during the chemical oxide formation process.

In FIG. 11B, a removal operation is performed that removes the nanostructures 24 entirely, substantially entirely or partially. In some embodiments, the nanostructures 24 are removed by a selective etching process using an etchant that is selective to the material of the nanostructures 24, such that the nanostructures 24 are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. Due to porosity of the oxide layers 240, the etching gas may enter through pores of the oxide layers 240 to attack the SiGe of the nanostructures 24 while being blocked by the oxide layers 220 such that the Si of the nanostructures 22 is not substantially attacked at side surfaces thereof. During the etching process that removes the nanostructures 24, some silicon of the nanostructures 22 may be removed, resulting in a reduced thickness of the nanostructures 22. In subsequent operations in which inner spacers 74 are formed in the NFET device region(s), the reduced thickness of the nanostructures 22 may result in increased height or thickness (e.g., in the Z-axis direction) of the inner spacers 74 in the NFET device region(s). Loss of thickness in the nanostructures 22 may be in a range of about 0.5 nm to about 2 nm. Partial removal of the nanostructures 24 resulting in a thin layer of low-concentration SiGe on upper and/or lower surfaces of the channels 22 may be beneficial for reducing lattice mismatch when growing the germanium layers 24G in a subsequent operation.

In FIG. 11C, following removal of the nanostructures 24, the germanium layers 24G may be formed in spaces previously occupied by the nanostructures 24, namely vertically between neighboring channels 22 (e.g., between the channels 22B and 22C). In embodiments in which the topmost nanostructure 24 is present on the uppermost channel 22C, a germanium layer 24G may also be formed on an upper surface of the uppermost channel 22C. As described with reference to FIG. 1, to improve tensile strain in NFETs (e.g., the nanostructure device 20A), the nanostructures or interposers 24 are replaced by substantially pure germanium layers or interposers 24G. The substantially pure Ge layers 24G may have germanium concentration that exceeds about 98%, exceeds about 99%, exceeds about 99.9%, exceeds about 99.99%, or the like. In some embodiments, the germanium layers 24G are high-concentration Ge layers 24G that have Ge concentration that exceeds about 80%, about 85%, about 90%, or the like. In some embodiments, the interposers 24G are Ge-alloy layers 24G (e.g., SiGe layers) that have Ge concentration that exceeds about 50%, about 60%, about 70%, or the like.

The interposers 24G may be formed by an epitaxial growth process that includes CVD, such as low-pressure CVD, ALD, or the like. A germanium precursor gas, such as germane (GeH4) may be flowed into a heated chamber under reduced pressure. The precursor may decompose on exposed regions of the hot substrate, such as the exposed upper and/or lower surfaces of the channels 22, resulting in layer-by-layer deposition of pure or substantially pure germanium atoms on the channels 22. In embodiments in which pure or substantially pure Ge layers 24G are formed, germane may be the only precursor gas flowed into the chamber. In embodiments in which high-concentration Ge layers 24G or Ge-alloy layers 24G are formed, germane and silane (SiH4) may be flowed simultaneously into the chamber. Although the interposers 24G are described in the above as germanium-containing semiconductor layers that have germanium concentration that exceeds about 50%, such as about 99.99% or even 100%, it should be understood that other material layers may be formed on the channels 22 that have qualities beneficial for increasing tensile strain beyond that which can be achieved via the nanostructures 24 that have germanium concentration less than about 40%. For example, instead of pure or high-concentration germanium, a semiconductor such as ZnSe, AlInAs or GaSb may be grown on the channels 22 to increase tensile strain thereof via lattice mismatch, thermal expansion mismatch or both. Pure or high-concentration germanium may have benefits of simpler integration into nanostructure device manufacturing processes that already use silicon and germanium, e.g., for forming the SiGe nanostructures 24.

In FIG. 11D, following formation of the replacement interposers 24G, the oxide layers 220, 240 are removed and recesses 64 are formed in which inner spacers 74 will be formed in a subsequent operation. The oxide layers 220, 240 may be removed by a suitable etching process, such as a wet etch that removes the oxide layers 220, 240 without substantially attacking other exposed layers, e.g., the spacer layers 41. Formation of the recesses 64 may be similar in most respects to that described with reference to FIG. 6D. For example, a selective etching process is performed to recess end portions of the replacement interposers 24G without substantially attacking the nanostructures 22. In some embodiments, the etching process that recesses the end portions of the replacement interposers 24G thins the ends of the channels 22, such that end portions of the channels 22 have thickness that is less than thickness in middle portions of the channels 22 that are in contact with the replacement interposers 24G.

In FIGS. 12A-12E, the recesses 64 are formed prior to forming the replacement interposers 24G.

In FIG. 12A, a selective etching process is performed to recess end portions of the nanostructures 24 without substantially attacking the nanostructures 22. End portions of the nanostructures 22 may be thinned slightly by the selective etching process, as depicted in FIG. 12A.

In FIG. 12B, the oxide layers 220, 240 are formed on the channels 22 and the nanostructures 24 via a process that is similar in most respects to that described with reference to FIG. 11A. In FIG. 12B, the oxide layers 220 extend to upper and lower surfaces of end portions of the channels 22 in addition to the side surfaces of the channels 22 and the oxide layers 240 are set inward somewhat from the outer side surfaces of the channels 22 along the X-axis direction.

In FIG. 12C, the nanostructures 24 are removed via a process similar to that described with reference to FIG. 11B. In the embodiments described with reference to FIGS. 11A-11D, the end portions of the channels 22 are subjected to etching twice, once during removal of the nanostructures 24 and once during formation of the recesses 64. In the embodiments described with reference to FIGS. 12A-12E, the end portions of the channels 22 are subjected to etching once during formation of the recesses 64 and are not subjected to etching during removal of the nanostructures 24 due to protection of the oxide layer 220. As such, the end portions of the channels 22 may have thickness that is slightly less than that of the middle portions of the channels 22 when the process of FIGS. 11A-11D is performed and may have uniform or substantially uniform thickness with the middle portions when the process of FIGS. 12A-12E is performed.

In FIG. 12D, the replacement interposers 24G are formed via a process similar in most respects to that described with reference to FIG. 11C. In the embodiments of FIGS. 12A-12E, the replacement interposers 24G may not be etched further due to the recesses 64 already having been formed in a prior operation described with reference to FIG. 12B. Namely, the replacement interposers 24G formed in FIG. 12D are substantially complete once a formation operation (e.g., epitaxial growth of germanium) is completed. The replacement interposers 24G in FIG. 12D may be formed to a width that is less than that of the channels 22 due to the presence of the oxide layers 220.

In FIG. 12E, the oxide layers 220, 240 are removed via a process that is similar in most respects to that described with reference to FIG. 11D.

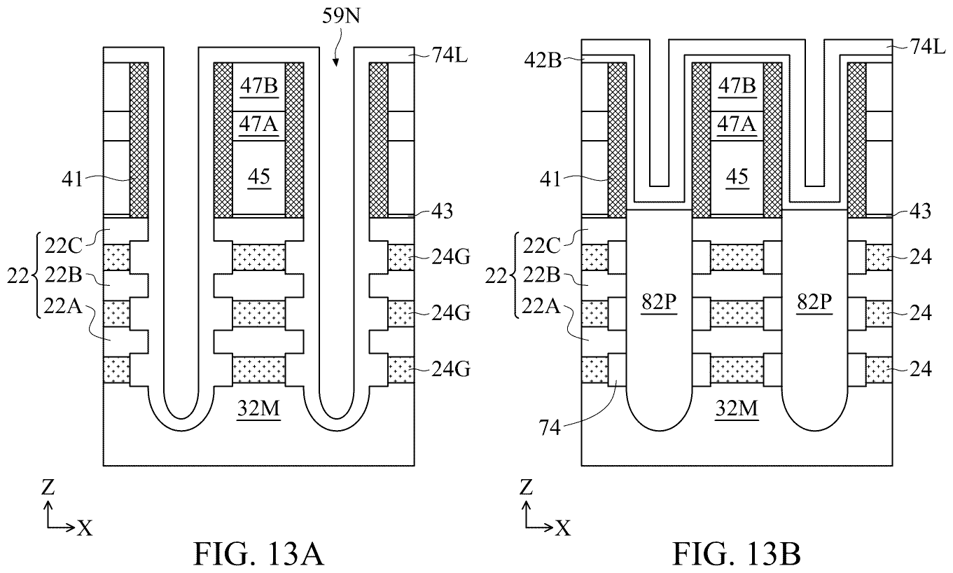

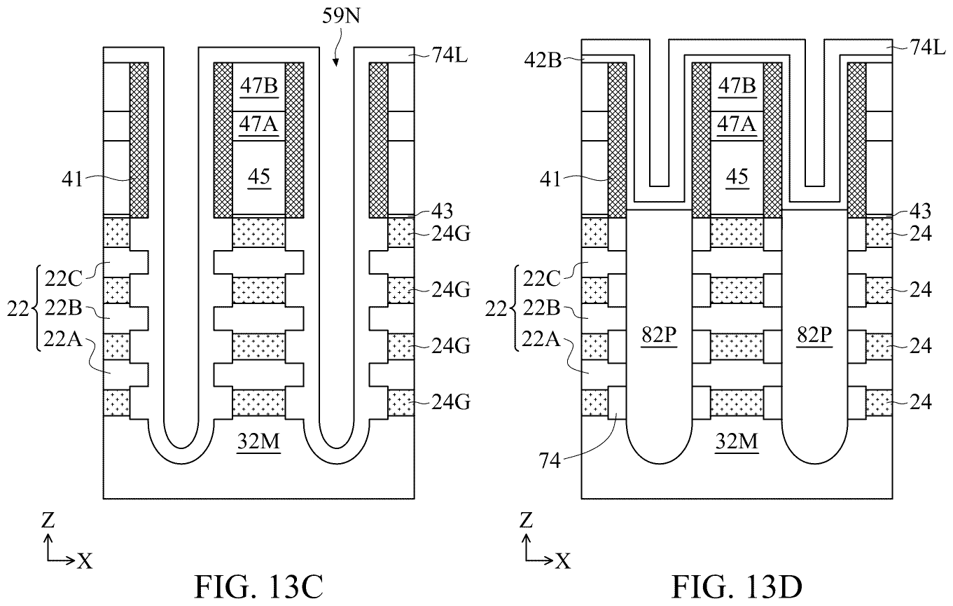

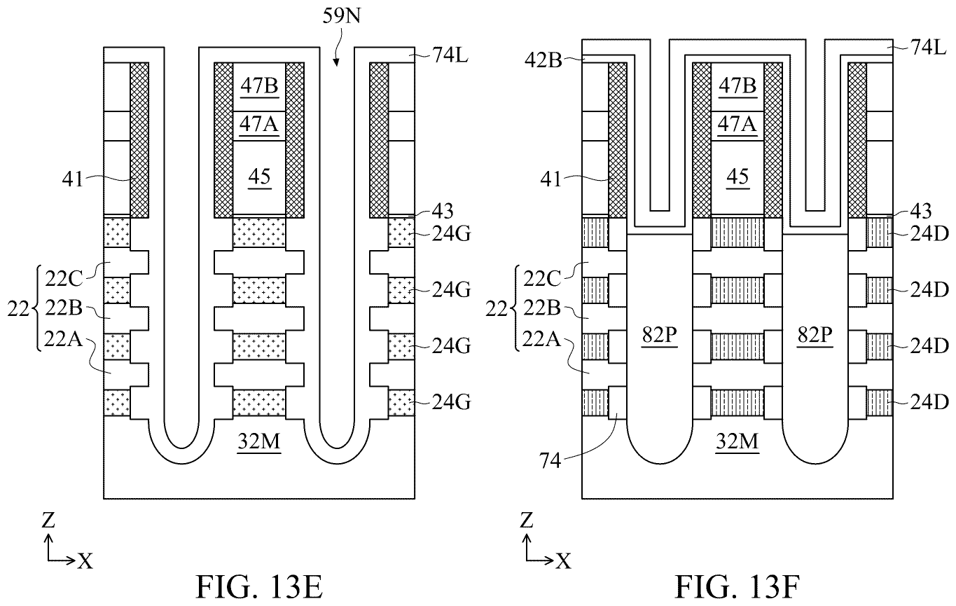

In FIGS. 13A-13F, an inner spacer layer 74L is formed via a process similar in most respects to that described with reference to FIGS. 7A-7F. In FIGS. 13A-13F, the inner spacer layer 74L is formed to fill the recesses 64 in the NFET device region(s) while the PFET device region(s) is protected by the second sacrificial spacer layer 42B.

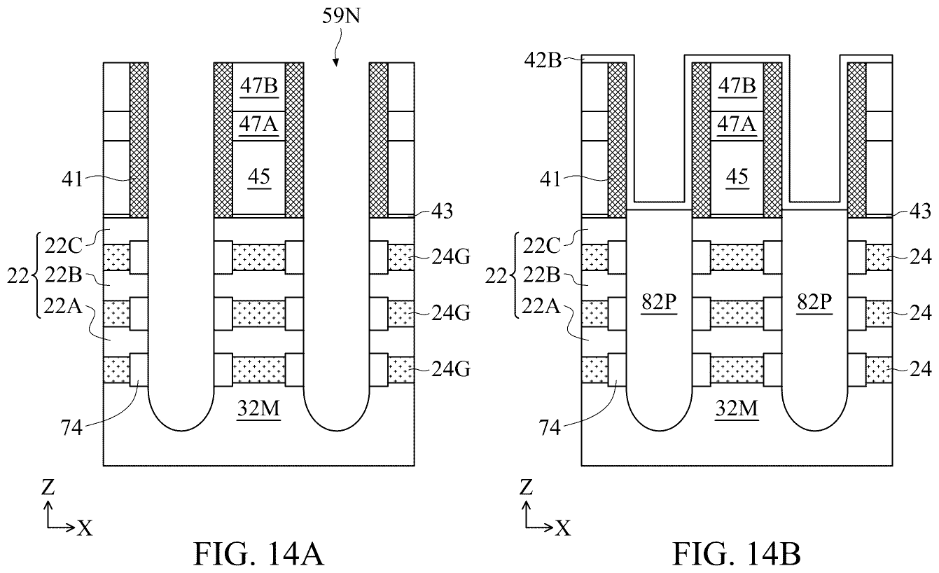

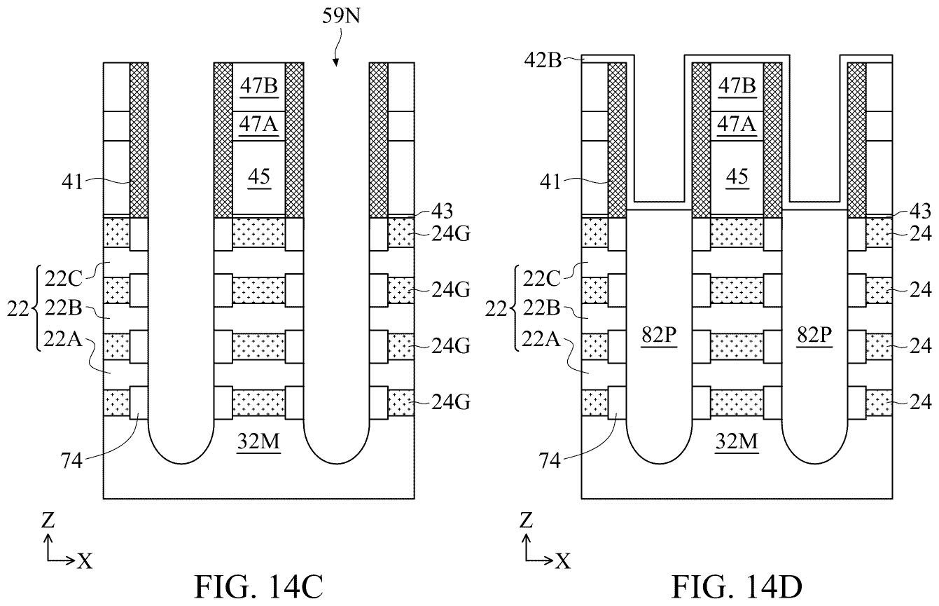

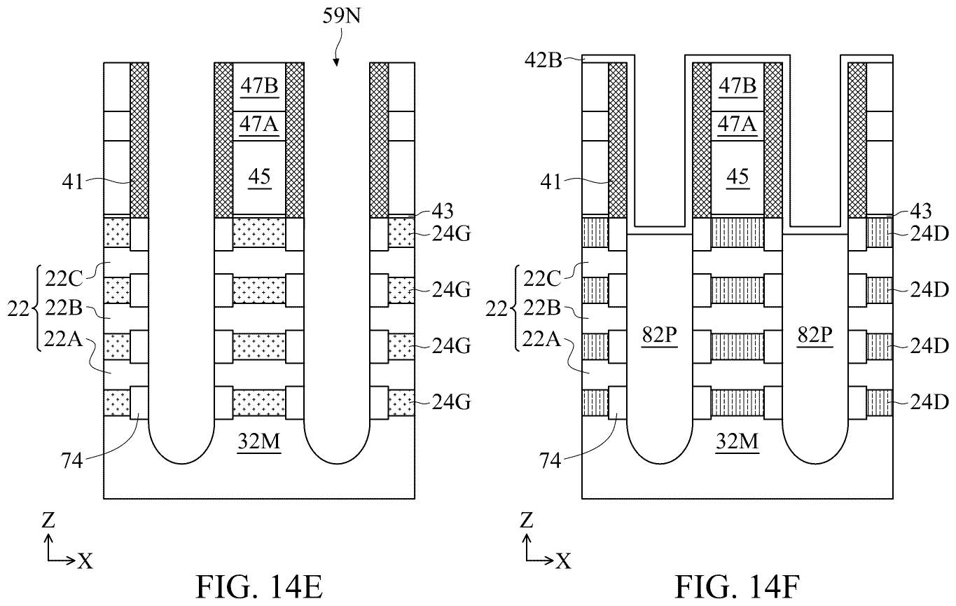

In FIGS. 14A-14F, the inner spacers 74 are formed via a process similar in most respects to that described with reference to FIGS. 8A-8F. In FIGS. 14A-14F, the inner spacers 74 are formed in the NFET device region(s). The inner spacers 74 abut the interposers 24G on either end thereof. As described with reference to FIG. 1, due to additional etching of the channels 22 during replacement of the interposers 24 with the interposers 24G, the inner spacers 74 in the NFET device region(s) may have thickness/height in the Z-axis direction that exceeds that of the inner spacers 74 in the PFET device region(s). This may be more pronounced in the embodiments depicted in FIGS. 14A-14D in which the interposers 24 are not replaced in the PFET device region(s) than in the embodiments depicted in FIGS. 14E and 14F in which the interposers 24 are replaced with the dielectric layers 24D. Namely, in FIGS. 14E and 14F, the inner spacers 74 in the NFET and PFET device regions may have thickness/height in the Z-axis direction that is substantially the same as each other or slightly different from each other.

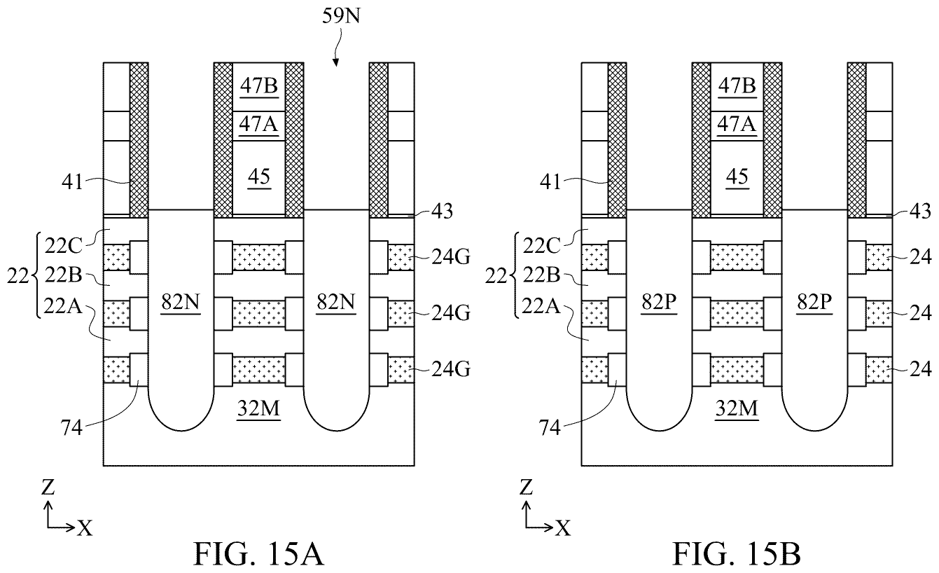

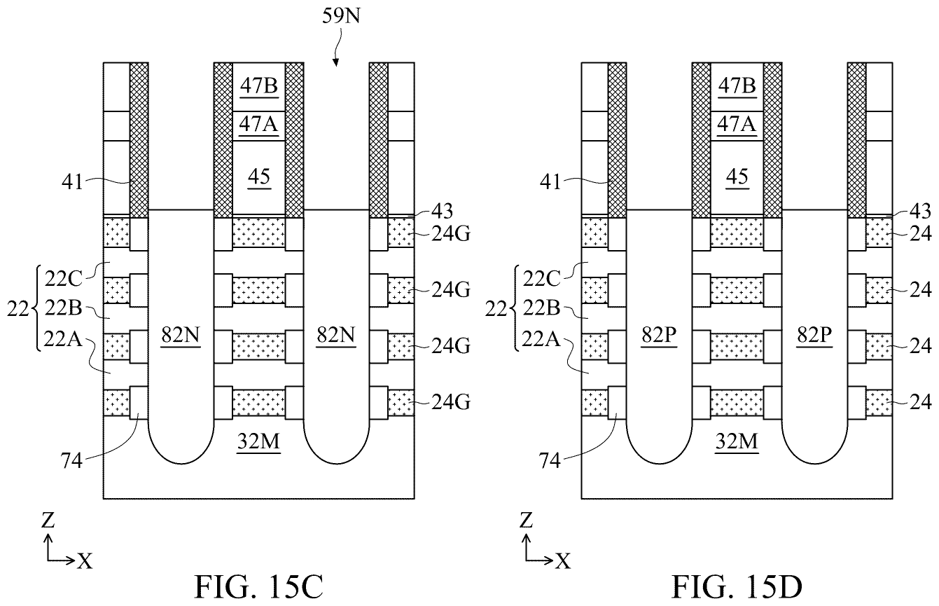

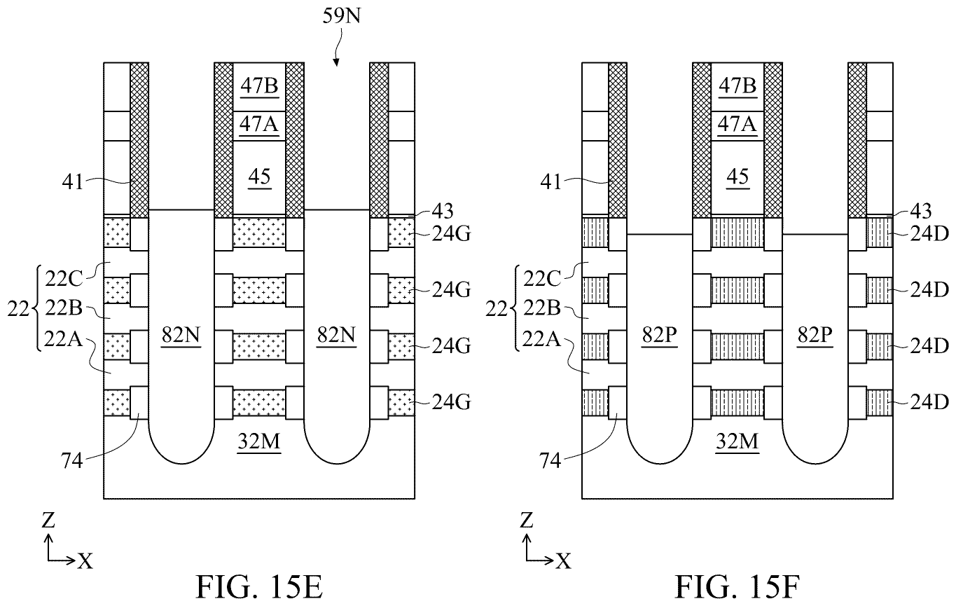

In FIGS. 15A-15F, second source/drains or second source/drain regions 82N are formed, corresponding to act 1500 of FIG. 21. The second source/drain regions 82N may be epitaxially grown from epitaxial material(s). In some embodiments, the source/drain regions 82N exert stress in the respective channels 22A, 22B, 22C, thereby improving performance. The source/drain regions 82N are formed such that each dummy gate structure 40 is disposed between respective neighboring pairs of the source/drain regions 82N. In some embodiments, the spacer layer 41 separates the source/drain regions 82N from the dummy gate layer 45 by an appropriate lateral distance to prevent electrical bridging to subsequently formed gates of the resulting device. The source/drain regions 82N may be or include SiP, SiAs, SiSb, SiPAs, SiP:As:Sb or the like. The source/drain regions 82N may exert a tensile strain in the channel regions 22.

In FIGS. 15A-15F, following formation of the second source/drains 82N, the second sacrificial spacer layer 42B may be removed in the PFET device region(s). Removal of the second sacrificial spacer layer 42B may be similar in most respects to that described with reference to FIGS. 8A-8F.

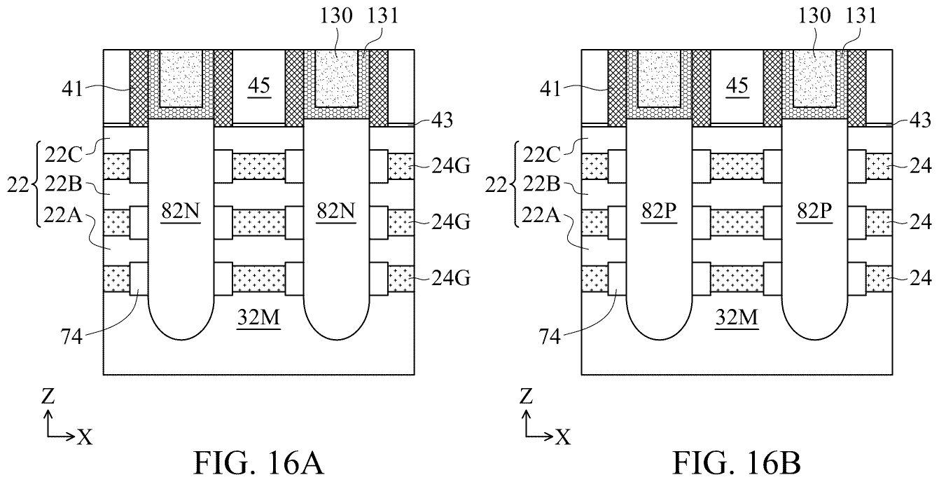

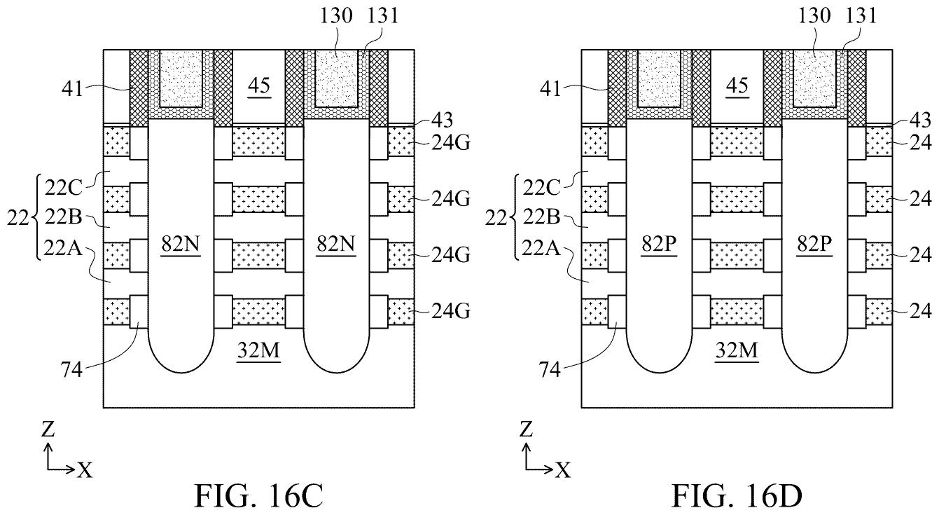

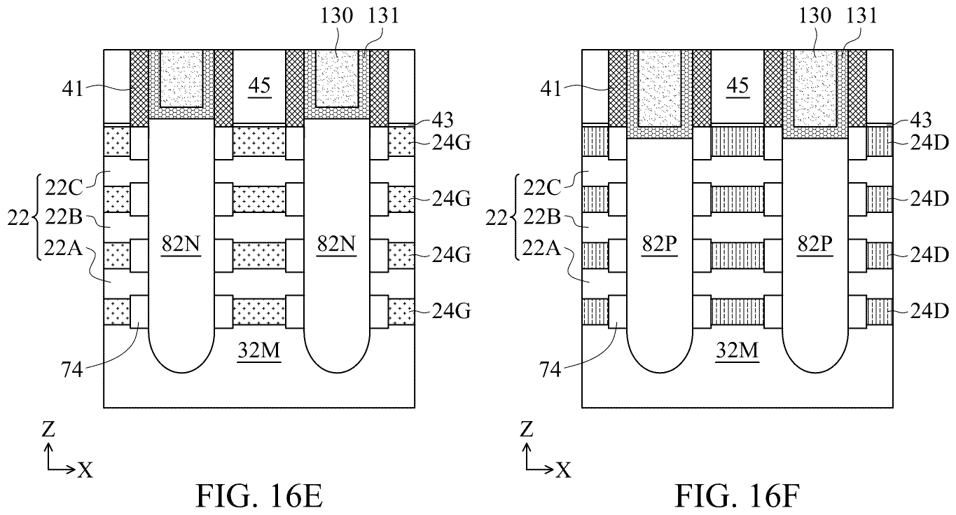

In FIGS. 16A-16F, following formation of the second source/drain regions 82N, the ILD 130 may be formed covering the source/drain regions 82N, 82P and abutting the spacer layer 41. In some embodiments, the ESL 131 is formed prior to forming the ILD 130. The ESL 131 may be formed by depositing a conformal thin layer of a dielectric material different from that of the ILD 130, such as one or more of SiN, SiCN, SiC, SiOC, SiOCN, HfO2, ZrO2, ZrAlOx, HfAlOx, HfSiOx, Al2O3, or other suitable material. Following deposition of the ESL 131, the ILD 130 may be deposited by a suitable process, such as a blanket deposition process, including PVD, CVD, ALD, or the like. The material of the ILD 130 may include silicon dioxide or a low-k dielectric material (e.g., a material having a dielectric constant (k-value) lower than the k-value (about 3.9) of silicon dioxide). The low-k dielectric material may include silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOxCy), Spin-On-Glass (SOG) or a combination thereof. The ILD 130 may be deposited by spin-on coating, CVD, Flowable CVD (FCVD), PECVD, PVD, or another deposition process.

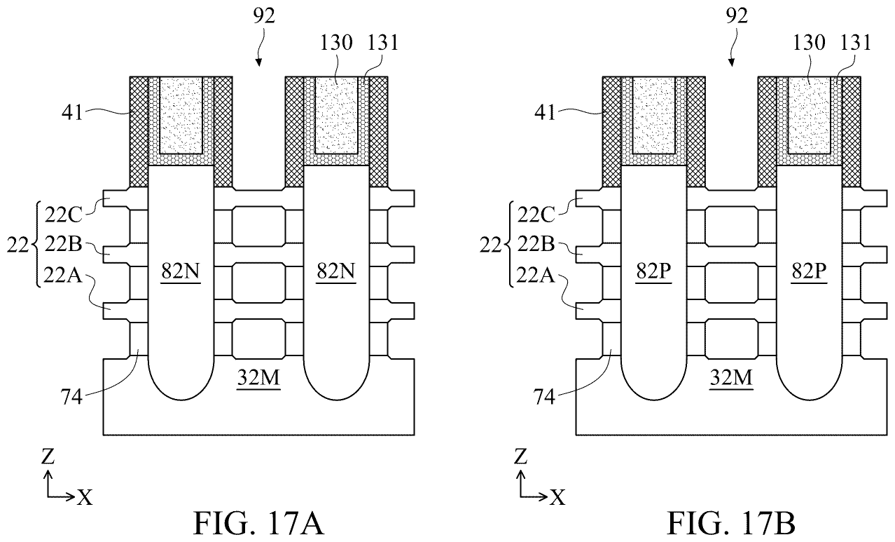

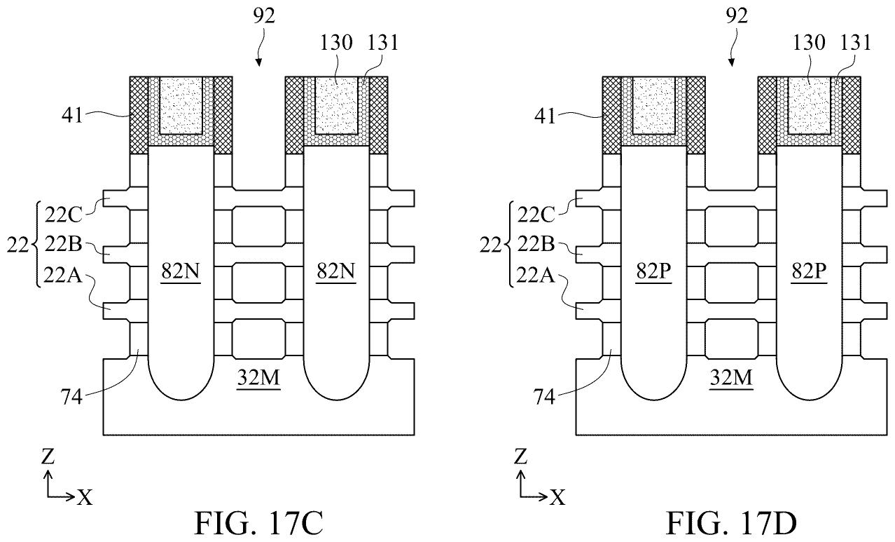

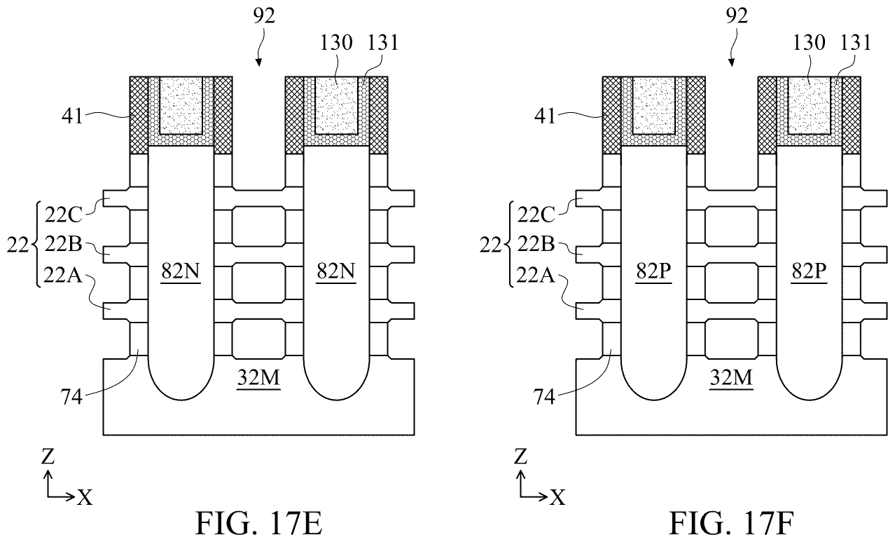

In FIGS. 17A-17F, following formation of the source/drains 82N, 82P, the ESL 131 and the ILD 130, active or replacement gate structures 200 may be formed. A planarization process, such as a chemical mechanical polishing (CMP) process, is performed on the ILD 130 and the ESL 131. The hard masks 47A, 47B and portions of the gate spacers 41 are also removed in the planarization process. After the planarization process, the dummy gate layers 45 are exposed. The top surfaces of the ILD 130 and the ESL 131 may be coplanar with the top surfaces of the dummy gate layers 45 and the gate spacers 41.

Next, as depicted in FIGS. 17A-17F, the dummy gate layer 45 is removed in an etching process, so that openings 92 are formed. In some embodiments, the dummy gate layer 45 is removed by an anisotropic dry etch process. For example, the etching process may include a dry etch process using reaction gas(es) that selectively etch the dummy gate layer 45 without etching the spacer layer 41. The dummy gate dielectric 43, when present, may be used as an etch stop layer when the dummy gate layer 45 is etched. The dummy gate dielectric 43 may then be removed after the removal of the dummy gate layer 45.

The replacement interposers 24G and the nanostructures 24 or the dielectric layers 24D are removed to release the nanostructures 22, corresponding to acts 1600, 2600 of FIGS. 21, 22, respectively. FIGS. 17A-17D depict embodiments in which the nanostructures 24 are removed. FIGS. 17E and 17F depict embodiments in which the dielectric layers 24D are removed. After the interposers 24G and the nanostructures 24 or the dielectric layers 24D are removed, the nanostructures 22 form a plurality of nanosheets that extend horizontally (e.g., parallel to a major upper surface of the substrate 110). Removal of the replacement interposers 24G and the nanostructures 24 or the dielectric layers 24D may be by one or more selective etching processes that use an etchant that is selective to the material of the nanostructures 24, interposers 24G or dielectric layers 24D, such that the nanostructures 24, interposers 24G or dielectric layers 24D are removed without substantially attacking the nanostructures 22. In some embodiments, the etching process is an isotropic etching process using an etching gas, and optionally, a carrier gas, where the etching gas comprises F2 and HF, and the carrier gas may be an inert gas such as Ar, He, N2, combinations thereof, or the like. In embodiments including the dielectric layers 24D, the material of the dielectric layers 24D may be selected to have different etch selectivity and/or be different than the material(s) of the ILD 130, ESL 131, fin spacers 41 and isolation regions 36, which is beneficial to avoid attacking the ILD 130, ESL 131, fin spacers 41 and isolation regions 36 when removing the dielectric layers 24D. In some embodiments, the NFET device region(s) is masked while the nanostructures 24 or dielectric layers 24D are removed in the PFET device region(s). In some embodiments, the PFET device region(s) is masked while the nanostructures 24 or replacement interposers 24G are removed in the NFET device region(s).

In some embodiments, the nanosheets 22 are reshaped (e.g. thinned) by a further etching process to improve gate fill window. The reshaping may be performed by an isotropic etching process selective to the nanosheets 22. After reshaping, the nanosheets 22 may exhibit the dog bone shape in which middle portions of the nanosheets 22 are thinner than peripheral portions of the nanosheets 22 along the X direction.

In FIGS. 18A-18F, following release of the channels 22 in FIGS. 17A-17F, replacement gates 200 are formed, corresponding to acts 1700, 2700 of FIGS. 21, 22, respectively. The replacement gates 200 may be referred to as active gates 200 or gate structures 200. The gate structures 200 may be formed by a series of deposition operations, such as ALD cycles, that deposit the various layers of the gate structure 200 in the openings, described below with reference to FIG. 20.

In FIGS. 18A and 18B, the top channel 22C is above the highest inner spacers 74. The portion of the replacement gates 200 that is above the highest channel 22C is also entirely above the highest inner spacers 74. The gate spacer layers 41 are on the highest channel 22C In FIGS. 18C-18F, the highest inner spacers 74 are above the highest channel 22C. A lower portion of the portion of the replacement gates 200 that is higher than the highest channel is laterally adjacent to the highest inner spacers 74. Furthermore, the gate spacer layers 41 are on the highest inner spacers 74.

FIG. 20 is a detailed view of a portion of the gate structure 200. The gate structure 200 generally includes the interfacial layer (IL, or “first IL” below) 210, at least one gate dielectric layer 600, the work function metal layer 900, and the gate fill layer 290. In some embodiments, each replacement gate 200 further includes at least one of a second interfacial layer 240 or a second work function layer 700.

With reference to FIG. 20, in some embodiments, the first IL 210 includes an oxide of the semiconductor material of the substrate 110, e.g. silicon oxide. In other embodiments, the first IL 210 may include another suitable type of dielectric material. The first IL 210 has a thickness in a range between about 5 angstroms and about 50 angstroms.

Still referring to FIG. 20, the gate dielectric layer 600 is formed over the first IL 210. In some embodiments, an atomic layer deposition (ALD) process is used to form the gate dielectric layer 600 to control thickness of the deposited gate dielectric layer 600 with precision. In some embodiments, the ALD process is performed using between about 40 and 80 deposition cycles, at a temperature range between about 200 degrees Celsius and about 300 degrees Celsius. In some embodiments, the ALD process uses HfCl₄ and/or H₂O as precursors. Such an ALD process may form the first gate dielectric layer 220 to have a thickness in a range between about 10 angstroms and about 100 angstroms.

In some embodiments, the gate dielectric layer 600 includes a high-k dielectric material, which may refer to dielectric materials having a high dielectric constant that is greater than a dielectric constant of silicon oxide (k≈3.9). Exemplary high-k dielectric materials include HfO₂, HfSiO, HfSiON, HfTaO, HfTiO, HfZrO, ZrO₂, Ta₂O₅, or combinations thereof. In other embodiments, the gate dielectric layer 600 may include a non-high-k dielectric material such as silicon oxide. In some embodiments, the gate dielectric layer 600 includes more than one high-k dielectric layer, of which at least one includes dopants, such as lanthanum, magnesium, yttrium, or the like, which may be driven in by an annealing process to modify threshold voltage of the nanostructure devices 20A, 20B.

With further reference to FIG. 20, an optional second IL 240 is formed on the gate dielectric layer 600, and the second work function layer 700 is formed on the second IL 240. The second IL 240 promotes better metal gate adhesion on the gate dielectric layer 600. In many embodiments, the second IL 240 further provides improved thermal stability for the gate structure 200 and serves to limit diffusion of metallic impurities from the work function metal layer 900 and/or the work function barrier layer 700 into the gate dielectric layer 600. In some embodiments, formation of the second IL 240 is accomplished by first depositing a high-k capping layer (not illustrated for simplicity) on the gate dielectric layer 600. The high-k capping layer comprises one or more of the following: HfSiON, HfTaO, HfTiO, HfTaO, HfAlON, HfZrO, or other suitable materials, in various embodiments. In one embodiment, the high-k capping layer comprises titanium silicon nitride (TiSiN). In some embodiments, the high-k capping layer is deposited by an ALD using about 40 to about 100 cycles at a temperature of about 400 degrees C. to about 450 degrees C. A thermal anneal is then performed to form the second IL 240, which may be or comprise TiSiNO, in some embodiments. Following formation of the second IL 240 by thermal anneal, an atomic layer etch (ALE) with artificial intelligence (AI) control may be performed in cycles to remove the high-k capping layer while substantially not removing the second IL 240. Each cycle may include a first pulse of WCl₅, followed by an Ar purge, followed by a second pulse of O₂, followed by another Ar purge. The high-k capping layer is removed to increase gate fill window for further multiple threshold voltage tuning by metal gate patterning.

Further in FIG. 20, after forming the second IL 240 and removing the high-k capping layer, the work function barrier layer 700 is optionally formed on the gate structure 200, in accordance with some embodiments. The work function barrier layer 700 is or comprises a metal nitride, such as TiN, WN, MON, TaN, or the like. In a specific embodiment, the work function barrier layer 700 is TIN. The work function barrier layer 700 may have thickness ranging from about 5 A to about 20 A. Inclusion of the work function barrier layer 700 provides additional threshold voltage tuning flexibility. In general, the work function barrier layer 700 increases the threshold voltage for NFET transistor devices, and decreases the threshold voltage (magnitude) for PFET transistor devices.

The work function metal layer 900, which may include at least one of an N-type work function metal layer, an in-situ capping layer, or an oxygen blocking layer, is formed on the work function barrier layer 700, in some embodiments. The N-type work function metal layer is or comprises an N-type metal material, such as TiAlC, TiAl, TaAlC, TaAl, or the like. The N-type work function metal layer may be formed by one or more deposition methods, such as CVD, PVD, ALD, plating, and/or other suitable methods, and has a thickness between about 10 A and 20 A. The in-situ capping layer is formed on the N-type work function metal layer. In some embodiments, the in-situ capping layer is or comprises TIN, TiSiN, TaN, or another suitable material, and has a thickness between about 10 A and 20 A. The oxygen blocking layer is formed on the in-situ capping layer to prevent oxygen diffusion into the N-type work function metal layer, which would cause an undesirable shift in the threshold voltage. The oxygen blocking layer is formed of a dielectric material that can stop oxygen from penetrating to the N-type work function metal layer, and may protect the N-type work function metal layer from further oxidation. The oxygen blocking layer may include an oxide of silicon, germanium, SiGe, or another suitable material. In some embodiments, the oxygen blocking layer is formed using ALD and has a thickness between about 10 A and about 20 A.

FIG. 20 further illustrates the metal core layer 290. In some embodiments, a glue layer (not separately illustrated) is formed between the oxygen blocking layer of the work function metal layer and the metal core layer 290. The glue layer may promote and/or enhance the adhesion between the metal core layer 290 and the work function metal layer 900. In some embodiments, the glue layer may be formed of a metal nitride, such as TiN, TaN, MON, WN, or another suitable material, using ALD. In some embodiments, thickness of the glue layer is between about 10 A and about 25 A. The metal core layer 290 may be formed on the glue layer, and may include a conductive material such as tungsten, cobalt, ruthenium, iridium, molybdenum, copper, aluminum, or combinations thereof. In some embodiments, the metal core layer 290 may be deposited using methods such as CVD, PVD, plating, and/or other suitable processes. In some embodiments, a seam 510, which may be an air gap, is formed in the metal core layer 290 vertically between the channels 22A, 22B, 22C. In some embodiments, the metal core layer 290 is conformally deposited on the work function metal layer 900. The seam 510 may form due to sidewall deposited film merging during the conformal deposition. In some embodiments, the seam 510 is not present between the neighboring channels 22A, 22B, 22C.

In some embodiments, one or more of metal layers including the core layer 290 and the work function layers 700, 900 in PFET devices can include Ti, Al, Zn, W, Nb, Co and the like and total thickness of the combination of metal layers on the gate dielectric layer 600 may be in a range of about 0.5 nm to about 20 nm. In some embodiments, one or more of metal layers including the core layer 290 and the work function layers 700, 900 in NFET devices can include Ti and/or Al and the like and total thickness of the combination of metal layers on the gate dielectric layer 600 may be in a range of about 0.5 nm to about 20 nm.

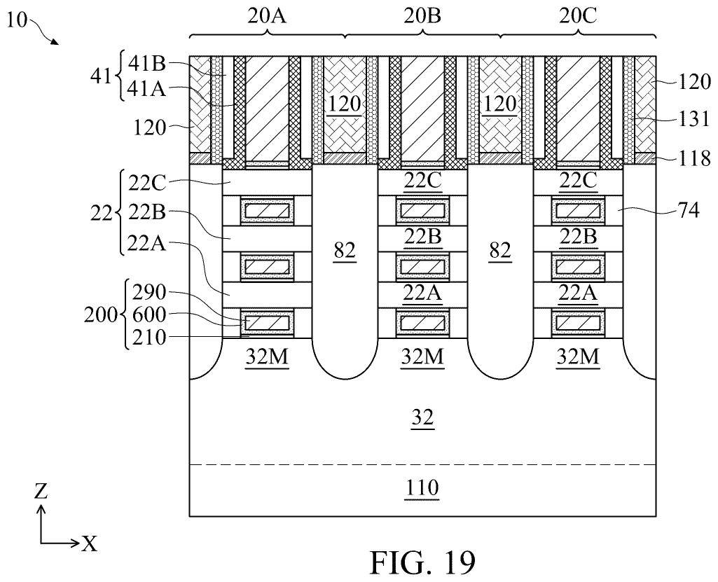

In FIG. 19, following formation of the gate structures 200, source/drain openings may be formed in the ILD 130 and source/drain contacts 120 may be formed in the source/drain openings. The first and second source/drains 82P, 82N may be referred to collectively as source/drains 82. Silicide regions 118 and the source/drain contacts 120 are formed on the source/drain regions 82.

In some embodiments, the silicide layers 118 are formed prior to or during formation of the source/drain contacts 120. For example, an N-type or P-type metal layer may be formed as a conformal thin layer over exposed portions of the source/drain regions 82. The metal layer may be or include one or more of Ni, Co, Mn, W, Fe, Rh, Pd, Ru, Pt, Ir, Os or the like. In some embodiments, the metal layer is or includes one or more of Ti, Cr, Ta, Mo, Zr, Hf, Sc, Ys, Ho, Tb, Gd, Lu, Dy, Er, Yb or another suitable material. Following formation of the metal layer, the silicide layers 118 may be formed by annealing the device 10. Following the anneal, the silicide layers 118 may be or include one or more of NiSi, CoSi, MnSi, Wsi, FeSi, RhSi, PdSi, RuSi, PtSi, IrSi, OsSi, TiSi, CrSi, TaSi, MoSi, ZrSi, HfSi, ScSi, Ysi, HoSi, TbSl, GdSi, LuSi, DySi, ErSi, YbSi or the like. Silicide of the silicide layers 118 may diffuse into regions below the ESL 131. Thickness of the silicide layers 118 may be in a range of about 1 nm to about 10 nm. Below about 1 nm, contact resistance may be too high. Above about 10 nm, the silicide layers 118 may short with the channels 22B.

Following or during formation of the silicide layers 118, the source/drain contacts 120 are formed by filling the openings over the source/drain regions 82 with, for example, a liner layer and a fill layer. In some embodiments, the source/drain contacts 120 are formed by depositing a material that is or includes a conductive material such as Co, W, Ru, combinations thereof, or the like. In some embodiments, the source/drain contacts 120 are or include a Co-, W- or Ru-based compound or alloy including one or more elements, such as Zr, Sn, Ag, Cu, Au, Al, Ca, Be, Mg, Rh, Na, Ir, W, Mo, Zn, Ni, K, Co, Cd, Ru, In, Os, Si, Ge, Mn, combinations thereof, or the like. The source/drain contacts 120 land on the silicide layer 118 and are in contact with the ESL 131. Description of the device 10 and illustration thereof in many of the figures is given with reference to GAAFETs including vertical stacks of the nanostructures 22. In some embodiments, the silicide layers 118 and the source/drain contacts 120 are formed in and on source/drain regions 82N, 82P of FinFET devices.

Additional processing may be performed to finish fabrication of the nanostructure devices 20. For example, gate contacts (or gate vias) may be formed to electrically couple to the gate structures 200. An interconnect structure may then be formed over the source/drain contacts 120 and the gate contacts. The interconnect structure may include a plurality of dielectric layers (including, for example, a second ILD) surrounding metallic features, including conductive traces and conductive vias, which form electrical connection between devices on the substrate 110, such as the nanostructure devices 20, as well as to IC devices external to the IC device 10.

Embodiments may provide advantages. Replacing the interposers 24 in the NFET device region(s), PFET device region(s) or both improves strain in channels 22 thereof. In the NFET device region(s), the interposers 24 are replaced by replacement interposers 24G that increase tensile strain of the channels 22. The replacement interposers 24G may be pure or substantially pure germanium layers or other suitable material layers. In the PFET device region(s), the interposers 24 may be replaced by dielectric layers 24D that reduce tensile strain and/or increase compressive strain.

In accordance with at least one embodiment, a method includes forming a stack of alternating first semiconductor layers and second semiconductor layers on a substrate and forming nanostructure channels and interposers by forming a source/drain opening in a first device region of the substrate. The source/drain opening extending through the first and second semiconductor layers. The method includes after the forming a source/drain opening, increasing tensile strain of the nanostructure channels. The method includes, after the increasing tensile strain, forming a source/drain in the source/drain opening.

A method for forming transistors includes forming a stack of alternating first semiconductor layers and second semiconductor layers on a substrate and forming nanostructure channels and interposers by forming a source/drain opening in a first device region of the substrate. The source/drain opening extending through the first and second semiconductor layers. The method includes, after the forming a source/drain opening, increasing tensile strain of the nanostructure channels, and, after the increasing tensile strain, forming a source/drain in the source/drain opening.

In accordance with at least one embodiment, a device includes a first stack of nanostructures in a first device region, a second stack of nanostructures in a second device region, and a first inner spacer positioned vertically between two adjacent nanostructures of the first stack of nanostructures. The device includes a second inner spacer positioned vertically between two adjacent nanostructures of the second stack of nanostructures, the first inner spacer having height that exceeds that of the second inner spacer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a stack of alternating first semiconductor layers and second semiconductor layers on a substrate;
forming nanostructure channels and interposers by forming a source/drain opening in a first device region of the substrate, the source/drain opening extending through the first and second semiconductor layers;
after the forming a source/drain opening, increasing tensile strain of the nanostructure channels; and
after the increasing tensile strain, forming a source/drain in the source/drain opening.

2. The method of claim 1, wherein the increasing tensile strain includes replacing the interposers with replacement interposers.

3. The method of claim 2, wherein the replacing the interposers includes replacing silicon germanium interposers with substantially pure germanium interposers having germanium concentration that exceeds about 99%.

4. The method of claim 2, wherein the replacing the interposers includes replacing silicon germanium interposers with high-concentration germanium interposers having germanium concentration that exceeds about 80%.

5. The method of claim 2, wherein the replacing the interposers includes replacing silicon germanium interposers having germanium concentration that does not exceed about 40% with silicon germanium interposers having germanium concentration that exceeds about 50%.

6. The method of claim 2, wherein the replacing the interposers with replacement interposers includes:
forming a first oxide layer on side surfaces of the nanostructure channels and a second oxide layer on side surfaces of the interposers, the second oxide layer being porous;
removing the interposers through pores of the second oxide layer; and
growing the replacement interposers through the pores of the second oxide layer.

7. The method of claim 2, further comprising:
forming first inner spacers abutting the replacement interposers; and
forming second inner spacers abutting second interposers in a second device region, the first inner spacers having height that exceeds height of the second inner spacers.

8. A method, comprising:
forming a stack of alternating first semiconductor layers and second semiconductor layers on a substrate;
forming nanostructure channels and interposers by forming a source/drain opening in a device region of the substrate, the source/drain opening extending through the first and second semiconductor layers;
after the forming a source/drain opening, reducing tensile strain of the nanostructure channels; and
after the reducing tensile strain, forming a source/drain in the source/drain opening.

9. The method of claim 8, wherein the reducing tensile strain includes replacing the interposers with replacement interposers.

10. The method of claim 9, wherein the replacing the interposers includes replacing the interposers with dielectric interposers.

11. The method of claim 10, wherein the replacing the interposers with dielectric interposers includes:
forming openings by removing the interposers exposed by the source/drain opening;
forming the dielectric interposers in the openings; and
forming recesses by recessing end portions of the dielectric interposers.

12. The method of claim 11, further comprising forming inner spacers in the recesses.

13. The method of claim 10, further comprising:
after the forming a source/drain, forming an opening by releasing the nanostructure channels by removing the dielectric interposers; and
forming a replacement gate in the opening.

14. The method of claim 8, further comprising, after the forming a source/drain:
forming second nanostructure channels and second interposers by forming a second source/drain opening in a second device region of the substrate;
after the forming a second source/drain opening, increasing tensile strain of the second nanostructure channels; and
after the increasing tensile strain, forming a second source/drain in the second source/drain opening.

15. A device, comprising:
a first stack of nanostructures in a first device region;
a second stack of nanostructures in a second device region;
a first inner spacer positioned vertically between two adjacent nanostructures of the first stack of nanostructures; and
a second inner spacer positioned vertically between two adjacent nanostructures of the second stack of nanostructures, the first inner spacer having height that exceeds that of the second inner spacer.

16. The device of claim 15, further comprising a third inner spacer positioned vertically above an uppermost nanostructure of the first stack of nanostructures.

17. The device of claim 15, wherein thickness of nanostructures of the first stack of nanostructures is thinner than thickness of nanostructures of the second stack of nanostructures.

18. The device of claim 17, wherein end portions of the nanostructures of the first stack of nanostructures have thickness that is thinner than thickness of middle portions of the nanostructures of the first stack of nanostructures.

19. The device of claim 15, further comprising a fin mesa underlying the first stack of nanostructures, wherein lattice constant of a first nanostructure directly overlying the fin mesa is larger than that of the fin mesa.

20. The device of claim 15, wherein an uppermost nanostructure of the first stack of nanostructures has lattice constant that is smaller than that of a nanostructure of the first stack of nanostructures that is between the uppermost nanostructure and a fin mesa that underlies the first stack of nanostructures.
